(19) United States
(12) Patent Application Publication
(10) Pub. No.: US 2026/0353994 A1
(43) Pub. Date: Nov. 5, 2026

(54) DISPLAY DEVICE AND ELECTRONIC DEVICE INCLUDING THE SAME

(71) Applicant: Samsung Display Co., Ltd., Yongin-si (KR)

(72) Inventors: TAEYOUNG SONG, Yongin-si (KR); SEONG-MIN KIM, Yongin-si (KR); JINKOO CHUNG, Yongin-si (KR)

(73) Assignee: Samsung Display Co., Ltd., Yongin-si (KR)

(21) Appl. No.: 19/660,893

(22) Filed: Apr. 28, 2026

(30) Foreign Application Priority Data
May 2, 2025 (KR) 10-2025-0058306

(51) Int. Cl. H10K 59/80; H10K 59/35

(52) U.S. Cl. CPC H10K 59/8792; H10K 59/353

(57) ABSTRACT

Provided is a display device including a display panel including a first pixel having a first viewing angle and a second pixel having a second viewing angle narrower than the first viewing angle, the first pixel and the second pixel in a display area, and a light control layer on the display panel, and including a light-blocking layer configured to control a path of light, wherein the display area includes a rib area in an area other than a light-emitting area, the first pixel, the second pixel, and the rib area are arranged in a predetermined pattern to form a pixel group, and the rib area is arranged repeatedly and discontinuously in a first direction and in a second direction intersecting the first direction.

### CROSS-REFERENCE TO RELATED APPLICATION

This application is based on and claims priority under 35 U.S.C. §119 to Korean Patent Application No. 10-2025-0058306, filed on May 2, 2025, in the Korean Intellectual Property Office, the disclosure of which is incorporated by reference herein in its entirety.

### BACKGROUND

### Field

One or more embodiments relate to a display device and an electronic device including the same.

### Description of Related Art

A display device is a device that receives information about an image and displays the image. The display device may be used as a display unit of a small product such as a mobile phone, or as a display unit of a large product such as a television.

A display device includes a plurality of pixels that receive electrical signals and emit light to display an image externally. Each of the pixels includes a light-emitting element. For example, an organic light-emitting display device includes an organic light-emitting diode (OLED) as a light-emitting element. Generally, in an organic light-emitting display device, a thin-film transistor and an OLED are formed on a substrate, and the OLED emits light by itself.

The applications of display devices have recently diversified. In addition, as the thickness and weight of display devices decrease, the range of applications for display devices is expanding, and the demand for display devices capable of providing high-quality images is increasing due to their use in various fields. In recent years, display devices have been disposed inside vehicles to provide images to users seated in the driver’s seat or the passenger seat.

### SUMMARY

The present disclosure may provide a display device that realizes high-quality images while supporting different viewing angles. However, the above objective is exemplary, and the scope of the present disclosure is not limited thereto.

One or more embodiments of the present disclosure may provide a display device including a display panel including a first pixel having a first viewing angle and a second pixel having a second viewing angle narrower than the first viewing angle, the first pixel and the second pixel in a display area, and a light control layer on the display panel, and including a light-blocking layer configured to control a path of light, wherein the display area includes a rib area in an area other than a light-emitting area, the first pixel, the second pixel, and the rib area are arranged in a predetermined pattern to form a pixel group, and the rib area is arranged repeatedly and discontinuously in a first direction and in a second direction intersecting the first direction.

In one or more embodiments of the present disclosure, the light-blocking layer may include a first light-blocking line extending in the first direction and a second light-blocking line extending in the second direction.

In one or more embodiments of the present disclosure, the first light-blocking line may be adjacent to the second pixel, but not to the first pixel, in the second direction.

In one or more embodiments one or more embodiments of the present disclosure, the second light-blocking line may be adjacent to the first pixel and the second pixel in the first direction.

In one or more embodiments of the present disclosure, the light-blocking layer may be between adjacent ones of the second pixels in the first direction, but the light-blocking layer may not be between adjacent ones of the first pixels in the first direction.

In one or more embodiments of the present disclosure, the pixel group may include a first pixel unit, a second pixel unit, a third pixel unit, and a fourth pixel unit, and the pixel group may be arranged repeatedly in the first direction and in the second direction.

In one or more embodiments of the present disclosure, the first pixel unit and the second pixel unit may be arranged alternately in the first direction, the first pixel unit and the third pixel unit may be arranged alternately in the second direction, and the third pixel unit and the fourth pixel unit may be arranged alternately in the first direction.

In one or more embodiments of the present disclosure, in the pixel group, the first pixel and the second pixel may be arranged alternately in the first direction.

In one or more embodiments of the present disclosure, the first pixel unit and the third pixel unit may include the rib area therein, and the second pixel unit and the fourth pixel unit may not include the rib area therein.

In one or more embodiments of the present disclosure, in the first pixel unit, the rib area, the first pixel, and the second pixel may be arranged sequentially in the first direction, and, in the third pixel unit, the first pixel, the rib area, and the second pixel may be arranged sequentially in the first direction.

In one or more embodiments of the present disclosure, in the display area, the first pixel, the rib area, and the first pixel may be arranged sequentially in the second direction.

In one or more embodiments of the present disclosure, in the first pixel unit, the first pixel, the second pixel, and the rib area may be arranged sequentially in the first direction, and, in the third pixel unit, the first pixel, the rib area, and the second pixel may be arranged sequentially in the first direction.

In one or more embodiments of the present disclosure, in the display area, the second pixel, the rib area, and the second pixel may be arranged sequentially in the second direction.

In one or more embodiments of the present disclosure, the first pixel may include a first sub-pixel, a second sub-pixel, and a third sub-pixel that may be configured to emit different colors, and the second pixel may include a fourth sub-pixel, a fifth sub-pixel, and a sixth sub-pixel that may be configured to emit different colors.

In one or more embodiments of the present disclosure, in the first pixel unit, the rib area, the first pixel, and the second pixel may be arranged sequentially in the first direction, or the first pixel, the rib area, and the second pixel may be arranged sequentially in the first direction, and, in the third pixel unit, the first pixel, the second pixel, and the rib area may be arranged sequentially in the first direction, or the first pixel, the rib area, and the second pixel may be arranged sequentially in the first direction.

In one or more embodiments of the present disclosure, in the first pixel unit, the rib area, the first sub-pixel, and the fourth sub-pixel may be arranged sequentially in the first direction, and the third sub-pixel, the rib area, and the sixth sub-pixel may be arranged sequentially in the first direction.

In one or more embodiments of the present disclosure, in the display area, the first sub-pixel, the rib area, the third sub-pixel, the rib area, and the second sub-pixel may be arranged sequentially as a whole in the second direction.

In one or more embodiments of the present disclosure, in the first pixel unit and the third pixel unit, a sequence in which the first sub-pixel, the second sub-pixel, the third sub-pixel, and the rib area are arranged in the first direction may be different for the first pixel unit and the third pixel unit.

In one or more embodiments of the present disclosure, in each of the first pixel unit and the third pixel unit, the rib area, the first pixel, and the second pixel may be arranged sequentially in the first direction, or the first pixel, the rib area, and the second pixel may be arranged sequentially in the first direction.

In one or more embodiments of the present disclosure, the display device may further include a first driving mode in which the first pixel is configured to be activated and a second driving mode in which the second pixel is configured to be activated.

One or more embodiments of the present disclosure may provide an electronic device including an input module configured to receive, from an external source, commands or data for use in the electronic device, at least one processor configured to process input data received from the input module and to output image data and/or command data, and a display device configured to implement one or more images by the at least one processor, wherein the display device includes a display panel including a first pixel having a first viewing angle and a second pixel having a second viewing angle narrower than the first viewing angle, the first pixel and the second pixel being in a display area, and a light-blocking layer on the display panel and including a light-blocking pattern configured to control a path of light, wherein the display area includes a rib area in an area other than a light-emitting area, the first pixel, the second pixel, and the rib area are arranged in a predetermined pattern to form a pixel group, and the rib area is arranged repeatedly and discontinuously in a first direction and in a second direction intersecting the first direction.

### BRIEF DESCRIPTION OF DRAWINGS

The above and other aspects, features, and advantages of certain embodiments of the present disclosure will be more apparent from the following description taken in conjunction with the accompanying drawings in which:

FIG. 1 is a perspective view schematically illustrating a display device according to one or more embodiments of the present disclosure;

FIG. 2 is a circuit diagram schematically illustrating a display element included in one pixel of the display device according to one or more embodiments of the present disclosure, and a pixel circuit connected to the display element;

FIG. 3 is a cross-sectional view schematically illustrating the display device according to one or more embodiments of the present disclosure;

FIG. 4 is a cross-sectional view schematically illustrating an electronic panel according to one or more embodiments of the present disclosure;

FIG. 5 is a cross-sectional view schematically illustrating the display device according to one or more embodiments of the present disclosure;

FIG. 6 is a cross-sectional view schematically illustrating a display device according to one or more embodiments of the present disclosure;

FIG. 7 is an enlarged plan view illustrating a portion of a display device according to one or more embodiments of the present disclosure;

FIG. 8 is a plan view illustrating an arrangement of a pixel group according to one or more embodiments of the present disclosure;

FIG. 9 is a cross-sectional view taken along line II-II′ of FIG. 7;

FIG. 10 is a cross-sectional view taken along line III-III′ of FIG. 7;

FIG. 11 is a perspective view schematically illustrating a mask assembly for thin film deposition according to one or more embodiments of the present disclosure;

FIGS. 12 to 14 are enlarged plan views each illustrating a portion of a mask sheet according to one or more embodiments of the present disclosure;

FIG. 15 is an enlarged plan view illustrating a portion of a display device according to one or more embodiments of the present disclosure;

FIG. 16 is an enlarged plan view illustrating a portion of a display device according to one or more embodiments of the present disclosure;

FIG. 17 is an enlarged plan view illustrating a portion of a display device according to one or more embodiments of the present disclosure;

FIG. 18 is an enlarged plan view illustrating a portion of a display device according to one or more embodiments of the present disclosure;

FIG. 19 is a block diagram of an electronic device according to one or more embodiments; and

FIG. 20 is a set of schematic views of electronic devices according to one or more embodiments.

### DETAILED DESCRIPTION

While the present disclosure is susceptible to various modifications and alternative forms, specific embodiments thereof are shown by way of example in the drawings and will herein be described in detail. Advantages and features of the present disclosure and methods for accomplishing the same will be more clearly understood from embodiments described below with reference to the drawings. However, the present disclosure is not limited to the embodiments disclosed below but may be implemented in various forms.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

In the following embodiments, singular forms are intended to include plural forms as well, unless the context clearly indicates otherwise.

It will be further understood that the terms “comprising”, “containing”, “including”, and/or “having” used herein specify the presence of stated features or components, but do not preclude the presence or addition of one or more other features or components.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

In addition, in the present disclosure, the meaning of “identical” includes cases where properties are similar to each other or similar within a certain range. Furthermore, identical means “substantially identical”. The meaning of substantially identical should be understood to include numerical values within manufacturing error ranges or differences within a range that is insignificant with respect to a reference numerical value as falling within the scope of ‘identical’.

As used herein, the terms “front (or forward)”, “rear (or back, rearward)”, “left”, “right”, “up (or top)”, “down (or bottom)” and the like may be defined with reference to the drawings, and may not be intended to limit the shape and position of each component.

Sizes of components in the drawings may be exaggerated or reduced for convenience of description. For example, the size and/or thickness of each component shown in the drawings are arbitrarily represented for convenience of description, and thus, the present disclosure is not necessarily limited thereto.

The phrase “a region/portion corresponds to a region/portion,” means that the region/portion overlaps the region/portion, and the regions/portions may not be limited to having the same area and/or the same shape.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

Hereinafter, exemplary embodiments of the present disclosure will be described below in detail with reference to the accompanying drawings, and when the embodiments of the present disclosure are described with reference to the drawings, the same or corresponding components may be given the same reference numerals, and repetitive descriptions thereof may be be omitted.

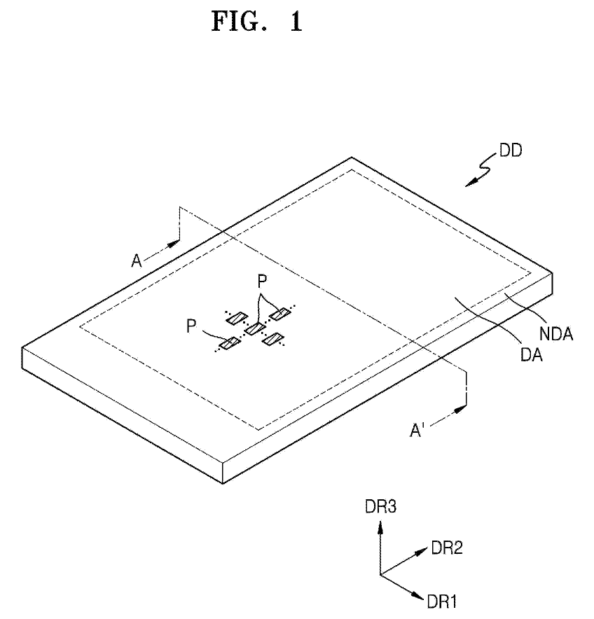

FIG. 1 is a perspective view schematically illustrating a display device according to one or more embodiments of the present disclosure.

Referring to FIG. 1, a display device DD according to one or more embodiments of the present disclosure may be a device that is activated in response to an electrical signal. Although the display device DD is illustrated as a mobile phone in FIG. 1, the scope of the present disclosure is not limited thereto.

The display device DD according to one or more embodiments of the present disclosure may include a display surface defined by a first direction DR1 and a second direction DR2 that intersects the first direction DR1. Images generated by the display device DD may be provided to a user through the display surface.

Hereinafter, a third direction DR3 is defined as a direction substantially perpendicular to a plane defined by the first direction DR1 and the second direction DR2. The third direction DR3 serves as a reference for distinguishing a front surface (top surface) and a rear surface (bottom surface) of each member. In the present specification, the terms “on the plane” and/or “in plan view” may be used to indicate a view or viewpoint that extends in or along the third direction DR3 (i.e., a top-down or “layout” view).

The display device DD according to one or more embodiments may include a display area DA and a non-display area NDA located outside the display area DA. In FIG. 1, the display area DA is illustrated as having an approximately rectangular shape, but the present disclosure is not limited thereto. The display area DA may have various shapes, such as a circular shape, an elliptical shape, or a polygonal shape.

The display area DA is a portion for displaying images, and a plurality of pixels P may be disposed in the display area DA. Hereinafter, the term “pixel” in the present specification may refer to a “sub-pixel.” Each of the pixels P may include a light-emitting element such as an organic light-emitting diode (OLED). Each of the pixels P may emit light of, for example, a red, green, blue, or white color.

The display area DA may provide a certain image using light emitted from the pixels P. In the present specification, the pixel P may be defined as a light-emitting area that emits light of any one of red, green, blue, or white color, as described above.

The non-display area NDA is a region in which no pixels P are disposed and which does not provide an image. In the non-display area NDA, components such as a terminal part connected to a driver integrated circuit (IC) or a printed circuit board (PCB) including power supply wirings and a driving circuit part for driving the pixels P may be disposed.

Hereinafter, an organic light-emitting display device will be described as an example of the display device DD according to one or more embodiments of the present disclosure. However, the display device DD according to one or more embodiments of the present disclosure is not limited thereto. The display device DD according to one or more embodiments may be a display device such as an inorganic light-emitting display device (also referred to as an inorganic electroluminescent (EL) display device), or a quantum dot light-emitting display device. For example, a light-emitting layer included in the light-emitting element provided in the display device DD may include an organic material or an inorganic material. For example, quantum dots may be located in a path of light emitted from the light-emitting layer.

In one or more embodiments, the display device DD according to one or more embodiments of the present disclosure may be applied not only to portable electronic devices such as a mobile phone, a smart phone, a tablet personal computer (PC), a mobile communication terminal, an electronic organizer, an electronic book, a portable multimedia player (PMP), a navigation device, and an ultra mobile PC (UMPC), but also to various products such as a television, a laptop computer, a monitor, a billboard, and an Internet of Things (IoT) device. The display device DD according to one or more embodiments may also be applied to wearable devices such as a smart watch, a watch phone, a glasses-type display, and a head mounted display (HMD). The display device DD according to one or more embodiments may also be applied to a display screen for a vehicle, such as an instrument panel, a center information display (CID) disposed on a center fascia or dashboard, a room mirror display that replaces a side mirror, or a rear-seat entertainment display disposed on a rear surface of a front seat.

The display device DD may include one or more folding areas and a plurality of non-folding areas. For example, a folding area may be disposed between the non-folding areas in the display device DD. That is, the display device may be folded so that the non-folding areas face each other, and may be folded inward so that the display surface is not exposed to an ambient and/or external environment (i.e., the outside). In one or more embodiments, the electronic device may be folded outward so that the display surface is exposed to the outside.

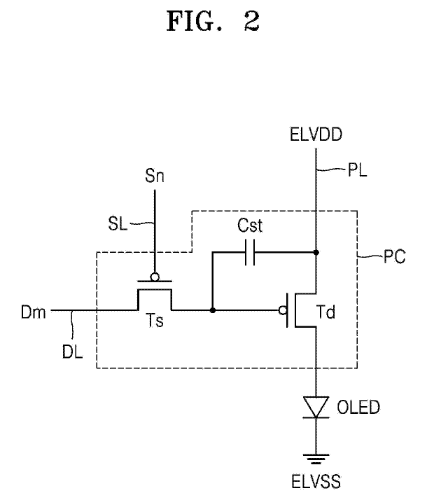

FIG. 2 is a circuit diagram schematically illustrating a display element included in one pixel of the display device according to one or more embodiments of the present disclosure, and a pixel circuit connected to the display element.

Referring to FIG. 2, each of the pixels P may include a pixel circuit PC, which is connected to a scan line SL and a data line DL, and an organic light-emitting diode OLED as a light-emitting element, which is connected to the pixel circuit PC.

The pixel circuit PC may include a driving thin-film transistor Td, a switching thin-film transistor Ts, and a storage capacitor Cst. The switching thin-film transistor Ts is connected to the scan line SL and the data line DL, and may transfer a data signal Dm input through the data line DL to the driving thin-film transistor Td in response to a scan signal Sn input through the scan line SL.

The storage capacitor Cst is connected to the switching thin-film transistor Ts and a drive voltage line PL, and may store a voltage corresponding to a difference between a voltage transmitted from the switching thin-film transistor Ts and a first power voltage ELVDD or drive voltage supplied through the drive voltage line PL.

The driving thin-film transistor Td is connected to the drive voltage line PL and the storage capacitor Cst, and may control a drive current flowing from the drive voltage line PL to the organic light-emitting diode OLED in response to a voltage value stored in the storage capacitor Cst. The organic light-emitting diode OLED may emit light having a certain luminance according to the drive current.

Although FIG. 2 illustrates an example in which the pixel circuit PC includes two thin-film transistors and one storage capacitor, the present disclosure is not limited thereto. In another embodiment, the pixel circuit PC may include, for example, seven thin-film transistors and one storage capacitor. In another embodiment, the pixel circuit PC may include two or more storage capacitors.

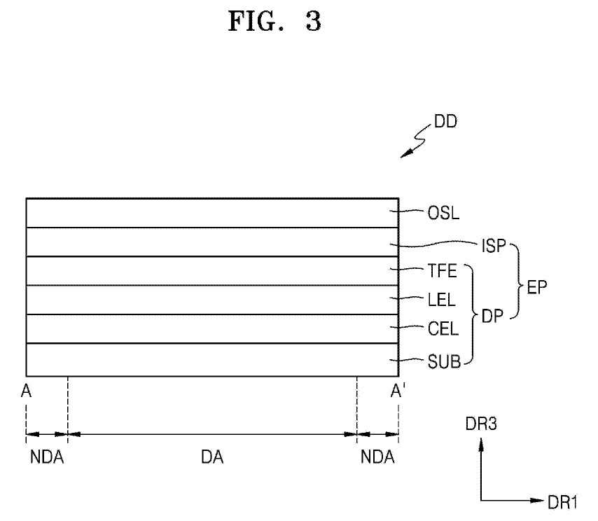

FIG. 3 is a cross-sectional view schematically illustrating the display device DD according to one or more embodiments of the present disclosure.

Referring to FIG. 3, the display device DD according to one or more embodiments may include an electronic panel EP and a light control layer OSL.

The electronic panel EP may include a display panel DP and an input sensor ISP disposed on the display panel DP. The display panel DP may include a base layer SUB, a circuit layer CEL disposed on the base layer SUB, a light-emitting element layer LEL disposed on the circuit layer CEL, and a thin-film encapsulation layer TFE disposed on the light-emitting element layer LEL.

The base layer SUB may provide a base surface on which the circuit layer CEL is disposed. The base layer SUB may be a flexible substrate that may be bendable, foldable, or rollable. The base layer SUB may be a glass substrate, a metal substrate, a polymer substrate, or the like. However, the embodiment of the present disclosure is not limited thereto, and the base layer SUB may be an inorganic layer, an organic layer, or a composite material layer.

The circuit layer CEL may be disposed on the base layer SUB. The circuit layer CEL may include insulating layers, transistors each including a semiconductor pattern, circuit wirings connected to the transistors, conductive patterns, and the like.

The light-emitting element layer LEL may be disposed on the circuit layer CEL. The light-emitting element layer LEL may include a light-emitting element. For example, the light-emitting element may include an organic light-emitting material, an inorganic light-emitting material, an organic-inorganic light-emitting material, quantum dots, quantum rods, micro light-emitting diodes (micro LEDs), or nano LEDs.

The thin-film encapsulation layer TFE may be disposed on the light-emitting element layer LEL. The thin-film encapsulation layer TFE may protect the light-emitting element layer LEL from foreign substances such as moisture, oxygen, and dust particles. The thin-film encapsulation layer TFE may include at least one inorganic layer. The thin-film encapsulation layer TFE may have a stacked structure of an inorganic layer, an organic layer, and another inorganic layer.

The input sensor ISP may include a plurality of electrodes for sensing external input, trace lines connected to the plurality of electrodes, and organic and/or inorganic layers for insulating and protecting the plurality of electrodes or the trace lines. The input sensor ISP may be a capacitive sensor, but the present disclosure is not particularly limited thereto.

The input sensor ISP may be directly disposed on the display panel DP. The display panel DP and the input sensor ISP may be formed through a continuous process. Accordingly, a separate adhesive layer may not be disposed between the input sensor ISP and the display panel DP.

The light control layer OSL may control the path of light provided from the display panel DP. The light control layer OSL may include a structure configured to control a path of light. The light control layer OSL may be disposed on the input sensor ISP. The light control layer OSL may be formed through a continuous process along with the display panel DP and the input sensor ISP, and may be directly disposed on the input sensor ISP. Alternatively, the light control layer OSL may be bonded to the input sensor ISP through an adhesive layer.

In one or more embodiments, a protective film, a window, or a functional coating layer that forms a front surface of the display device DD may be further disposed on the light control layer OSL.

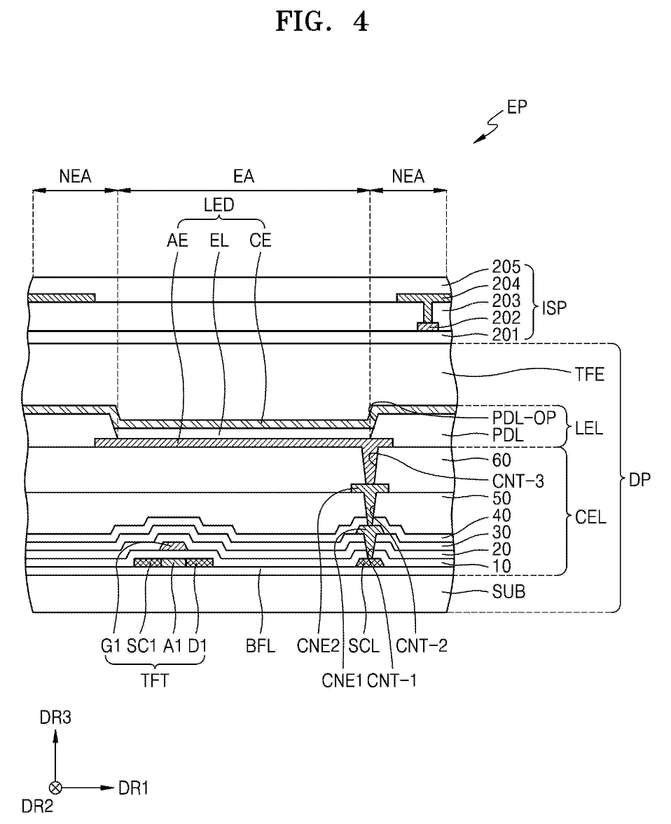

FIG. 4 is a cross-sectional view schematically illustrating the electronic panel EP according to one or more embodiments of the present disclosure. Although only one light-emitting area EA is illustrated in the drawing, this is merely exemplary, and a plurality of light-emitting areas EA may be provided.

Referring to FIG. 4, the electronic panel EP according to one or more embodiments of the present disclosure may include the display panel DP and the input sensor ISP.

Here, the display panel DP may include the base layer SUB, the circuit layer CEL, the light-emitting element layer LEL, and the thin-film encapsulation layer TFE.

The base layer SUB may have a multi-layer structure. For example, the base layer SUB may have a three-layer structure including a synthetic resin layer, an adhesive layer, and another synthetic resin layer. For example, the synthetic resin layer may include a polyimide-based resin. In one or more embodiments, the synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

The circuit layer CEL may be disposed on the base layer SUB. The circuit layer CEL may include an insulating layer, a semiconductor pattern, a conductive pattern, signal lines, a driving circuit for pixels, and the like. For example, the circuit layer CEL may include a buffer layer BFL, first to fifth insulating layers 10, 20, 30, 40, and 50, a signal transmission region SCL, and a plurality of connection electrodes CNE1 and CNE2.

The buffer layer BFL may be disposed on the base layer SUB. The buffer layer BFL may prevent metal atoms or impurities in the base layer SUB from diffusing into the semiconductor pattern formed thereon. The semiconductor pattern includes an active region A1 of a transistor TFT. A backside metal layer may additionally be disposed between the base layer SUB and the buffer layer BFL. The backside metal layer may be disposed below the transistor TFT and may block external light from reaching the transistor TFT.

The semiconductor pattern may be disposed on the buffer layer BFL. The semiconductor pattern may include a silicon semiconductor. For example, the silicon semiconductor may include amorphous silicon, polycrystalline silicon, or the like. For example, the semiconductor pattern may include low-temperature polysilicon.

The transistor TFT may include a source region (or source) SC1, an active region (or channel) A1, a drain region (or drain) D1, and a gate G1. The source region SC1, the active region A1, and the drain region D1 of the transistor TFT may be formed from the semiconductor pattern. In a cross-sectional view, the source region SC1 and the drain region D1 may extend in opposite directions from the active region A1. FIG. 4 illustrates a portion of the signal transmission region SCL formed from the semiconductor pattern. The signal transmission region SCL may be connected to the drain D1 of the transistor TFT in a plan view.

A first insulating layer 10 may be disposed on the buffer layer BFL. The first insulating layer 10 may cover the source SC1, the active region A1, the drain D1, and the signal transmission region SCL of the transistor TFT disposed on the buffer layer BFL.

The first insulating layer 10 may include an inorganic layer and/or an organic layer, and may have a single-layer structure or a multi-layer structure. The inorganic layer may include at least one of aluminum oxide, titanium oxide, silicon oxide, silicon nitride, silicon oxynitride, zirconium oxide, and hafnium oxide. In the present embodiment, the first insulating layer 10 may be a single-layer silicon oxide layer. Each of the insulating layers of the circuit layer CEL to be described below, as well as the first insulating layer 10, may be an inorganic layer and/or an organic layer and may have a single-layer structure or a multi-layer structure. The inorganic layer may include at least one of the above-described materials, but the present disclosure is not limited thereto.

The gate G1 of the transistor TFT may be disposed on the first insulating layer 10. The gate G1 may be a portion of a metal pattern. The gate G1 may overlap the active region A1. The gate G1 may serve as a mask in a process of doping the semiconductor pattern. The gate G1 may include titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), and the like, but the present disclosure is not particularly limited thereto.

A second insulating layer 20 may be disposed on the first insulating layer 10 and may cover the gate G1. A third insulating layer 30 may be disposed on the second insulating layer 20.

A first connection electrode CNE1 may be disposed on the third insulating layer 30. The first connection electrode CNE1 may be connected to the signal transmission region SCL through a contact hole CNT-1 that passes through the first to third insulating layers 10, 20, and 30. A fourth insulating layer 40 may be disposed on the third insulating layer 30 and may cover the first connection electrode CNE1. The fourth insulating layer 40 may be an organic layer.

A fifth insulating layer 50 may be disposed on the fourth insulating layer 40. A second connection electrode CNE2 may be disposed on the fifth insulating layer 50. The second connection electrode CNE2 may be connected to the first connection electrode CNE1 through a contact hole CNT-2 that passes through the fourth insulating layer 40 and the fifth insulating layer 50. The fifth insulating layer 50 may be an organic layer.

A sixth insulating layer 60 may be disposed on the fifth insulating layer 50 and may cover the second connection electrode CNE2. The sixth insulating layer 60 may be an organic layer. The stacked structure of the first to sixth insulating layers 10, 20, 30, 40, 50, and 60 is merely exemplary, and additional conductive and insulating layers may be further disposed in addition to the first to sixth insulating layers 10, 20, 30, 40, 50, and 60.

The light-emitting element layer LEL may be disposed on the circuit layer CEL. The light-emitting element layer LEL may include a light-emitting element LED and a pixel-defining film PDL. For example, the light-emitting element layer LEL may include an organic light-emitting material, quantum dots, quantum rods, micro LEDs, or nano LEDs.

The light-emitting element LED may include a first electrode AE, a light-emitting layer EL, and a second electrode CE.

The first electrode AE may be disposed on the sixth insulating layer 60. The first electrode AE may be connected to the second connection electrode CNE2 through a contact hole CNT3 that passes through the sixth insulating layer 60.

The pixel-defining film PDL may be disposed on the sixth insulating layer 60 and may cover a portion of the first electrode AE. An opening PDL-OP may be defined in the pixel-defining film PDL. The opening PDL-OP of the pixel-defining film PDL exposes at least a portion of the first electrode AE. In the present embodiment, the light-emitting area EA is defined to correspond to a partial area of the first electrode AE, which is exposed through the opening PDL-OP. A non-light-emitting area NEA may surround the light-emitting area EA.

The light-emitting layer EL may be disposed on the first electrode AE. The light-emitting layer EL may be disposed in the opening PDL-OP. That is, the light-emitting layer EL may be separately formed for each pixel. When the light-emitting layer EL is formed separately for each pixel, each of the light-emitting layers EL may emit light of at least one of blue, red, and green colors. However, the present disclosure is not limited thereto, and the light-emitting layer EL may also be commonly provided while being connected to the pixels. In this case, the light-emitting layer EL may emit blue light or white light.

The second electrode CE may be disposed on the light-emitting layer EL. The second electrode CE may have an integral shape and may be commonly disposed over a plurality of pixels. A common voltage may be supplied to the second electrode CE, and the second electrode CE may be referred to as a common electrode.

The light-emitting layer EL may be an organic light-emitting layer including an organic material. The light-emitting layer EL may include a hole transporting layer, an organic light-emitting layer, and an electron transporting layer. When the first electrode AE receives a certain voltage through a thin-film transistor of the circuit layer CEL, and the second electrode CE receives a common voltage, holes and electrons may move through the hole transporting layer and the electron transporting layer, respectively, into the organic light-emitting layer and may combine therein to emit light. For example, the first electrode AE may be an anode, and the second electrode CE may be a cathode, but the present disclosure is not limited thereto.

In another example, a plurality of light-emitting elements LED may include quantum dot light-emitting diodes including a quantum dot light-emitting layer, inorganic light-emitting diodes including an inorganic semiconductor, or micro light-emitting diodes.

The thin-film encapsulation layer TFE may be disposed on the second electrode CE. The thin-film encapsulation layer TFE may have a multi-layer structure in which at least one organic encapsulation layer and at least one inorganic encapsulation layer are alternately stacked. The thin-film encapsulation layer TFE serves to protect a display unit from external moisture penetration.

The organic encapsulation layer may provide a more planar base surface, which may reduce a defect rate even when the input sensor ISP, which will be described below, is formed through a continuous process.

The input sensor ISP may include a base insulating layer 201, a first conductive layer 202, a sensing insulating layer 203, a second conductive layer 204, and a cover insulating layer 205.

The base insulating layer 201 may be an inorganic layer including any one of silicon nitride, silicon oxynitride, and silicon oxide. Alternatively, the base insulating layer 201 may be an organic layer including an epoxy resin, an acrylic resin, or an imide-based resin. The base insulating layer 201 may have a single-layer structure or a multi-layer structure stacked in the third direction DR3.

Each of the first conductive layer 202 and the second conductive layer 204 may have a single-layer structure or a multi-layer structure stacked in the third direction DR3.

The conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO).

The conductive layer having a multi-layer structure may include metal layers. For example, the metal layers may have a three-layer structure of titanium/aluminum/titanium. The conductive layer having a multi-layer structure may include at least one metal layer and at least one transparent conductive layer.

At least one of the sensing insulating layer 203 and the cover insulating layer 205 may include an inorganic film. The inorganic film may include at least one of aluminum oxide, titanium oxide, silicon oxide, silicon oxynitride, zirconium oxide, and hafnium oxide.

At least one of the sensing insulating layer 203 and the cover insulating layer 205 may include an organic film. The organic film may include at least one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

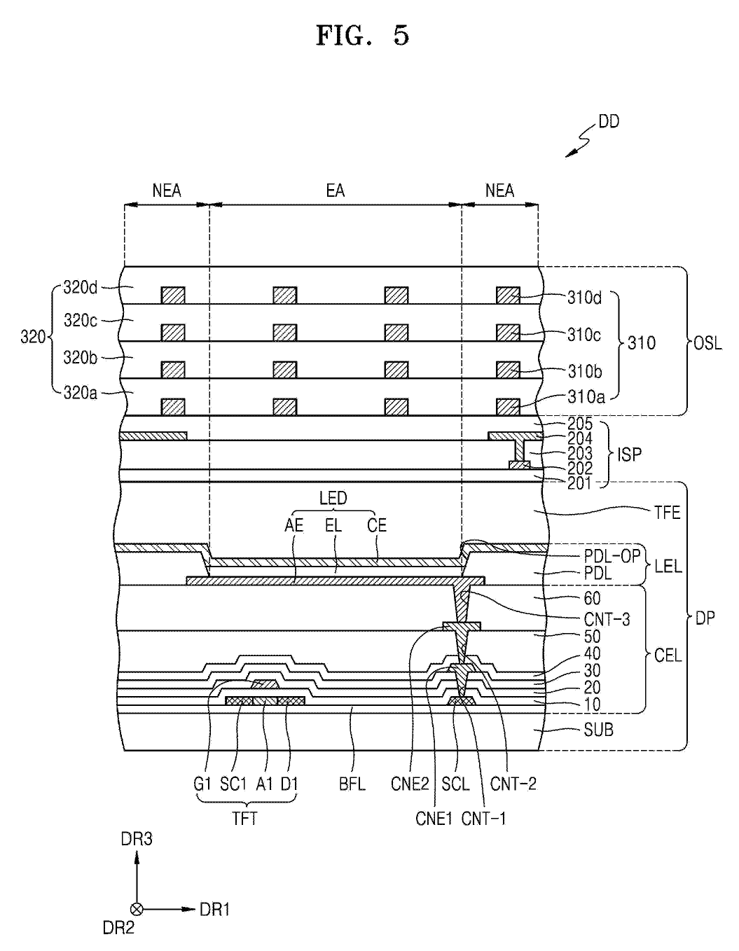

FIG. 5 is a cross-sectional view schematically illustrating a display device according to one or more embodiments of the present disclosure.

Referring to FIG. 5, the light control layer OSL may include the light-blocking layer 310 and the light-transmitting layer 320.

The light control layer OSL may include a plurality of sub-light control layers. For example, the light control layer OSL may include four sub-light control layers, but the present disclosure is not necessarily limited thereto. In one or more embodiments, the sub-light control layers may be sequentially stacked in a direction away from the light-emitting element LED.

The light-blocking layer 310 may include first to fourth light-blocking layers 310a, 310b, 310c, and 310d, each of which may be disposed in a corresponding sub-light control layer.

The first light-blocking layer 310a may be disposed on the input sensor ISP. The first light-blocking layer 310a may be disposed on the display area DA of the display panel DP. The first light-blocking layer 310a may overlap the first conductive layer 202 or the second conductive layer 204 in the third direction.

A plurality of first light-blocking layers 310a may be disposed to be spaced apart from each other, and some thereof may be disposed to overlap the light-emitting area EA.

The first light-blocking layer 310a may block or absorb light emitted from the display panel DP. The first light-blocking layer 310a may include a material that blocks or absorbs light. In one or more embodiments, the first light-blocking layer 310a may include a light-blocking organic material. For example, the first light-blocking layer 310a may include a light-blocking material capable of absorbing or blocking light, such as carbon black, an organic black pigment, a blue pigment, a blue dye, a green pigment, and/or a green dye. For example, the first light-blocking layer 310a may include an organic material such as an acryl resin, an epoxy resin, a phenolic resin, a polyamide resin, or a polyimide resin.

In one or more embodiments, a refractive index of the first light-blocking layer 310a may be lower than that of a first light-transmitting layer 320a. The refractive index of the first light-blocking layer 310a may be higher than that of some encapsulation layers included in the thin-film encapsulation layer TFE.

In one or more embodiments, the light-transmitting layer 320 may include first to fourth light-transmitting layers 320a, 320b, 320c, and 320d. The first light-transmitting layer 320a may be disposed on the first light-blocking layers 310a. The first light-transmitting layer 320a may fill openings formed between the first light-blocking layers 310a.

The first light-transmitting layer 320a may transmit light emitted from the display panel DP. In one or more embodiments, the first light-transmitting layer 320a may be an organic film including a transparent organic material capable of transmitting light. For example, the first light-transmitting layer 320a may include an organic film such as an acryl resin, an epoxy resin, a phenolic resin, a polyamide resin, or a polyimide resin. Alternatively, the first light-transmitting layer 320a may be an inorganic film capable of transmitting light. For example, the first light-transmitting layer 320a may be a silicon nitride layer, a silicon oxynitride layer, a silicon oxide layer, a titanium oxide layer, or an aluminum oxide layer.

The second light-blocking layer 310b may be disposed on the first light-transmitting layer 320a. The second light-blocking layer 310b may be disposed in the display area of the display panel DP. The second light-blocking layer 310b may have the same shape as the first light-blocking layer 310a.

The second light-blocking layer 310b may overlap the first conductive layer 202 or the second conductive layer 204 in the third direction. A plurality of second light-blocking layers 310b may be disposed to be spaced apart from each other, and some thereof may be disposed to overlap the light-emitting area EA. The second light-blocking layer 310b may be disposed to overlap the first light-blocking layer 310a.

The second light-blocking layer 310b may block or absorb light emitted from the display panel DP. The second light-blocking layer 310b may include a material that blocks or absorbs light. In one or more embodiments, the second light-blocking layer 310b may include a light-blocking organic material. The second light-blocking layer 310b may include the same material as the first light-blocking layer 310a.

In one or more embodiments, a refractive index of the second light-blocking layer 310b may be lower than that of the second light-transmitting layer 320b.

The second light-transmitting layer 320b may be disposed on the second light-blocking layers 310b. The second light-transmitting layer 320b may fill openings formed between the second light-blocking layers 310b.

The second light-transmitting layer 320b may transmit light emitted from the display panel DP. In one or more embodiments, the second light-transmitting layer 320b may be an organic film including a transparent organic material capable of transmitting light.

For example, the second light-transmitting layer may include the same organic material as the first light-transmitting layer 320a described above. Alternatively, the second light-transmitting layer 320b may be an inorganic film capable of transmitting light.

The third light-blocking layer 310c may be disposed on the second light-transmitting layer 320b. The third light-blocking layer 310c may be disposed in the display area of the display panel DP. The third light-blocking layer 310c may have the same shape as the second light-blocking layer 310b.

The third light-blocking layer 310c may overlap the first conductive layer 202 or the second conductive layer 204 in the third direction. A plurality of third light-blocking layers 310c may be disposed to be spaced apart from each other, and some thereof may be disposed to overlap the light-emitting area EA. The third light-blocking layer 310cmay be disposed to overlap the second light-blocking layer 310b.

The third light-blocking layer 310c may block or absorb light emitted from the display panel DP. The third light-blocking layer 310c may include a material that blocks or absorbs light. In one or more embodiments, the third light-blocking layer 310c may include a light-blocking organic material. The third light-blocking layer 310c may include the same material as the first light-blocking layer 310a.

In one or more embodiments, a refractive index of the third light-blocking layer 310c may be lower than that of the third light-transmitting layer 320c.

The third light-transmitting layer 320c may be disposed on the third light-blocking layers 310c. The third light-transmitting layer 320c may fill openings formed between the third light-blocking layers 310c.

The third light-transmitting layer 320c may transmit light emitted from the display panel DP. In one or more embodiments, the third light-transmitting layer 320c may be an organic film including a transparent organic material capable of transmitting light.

For example, the third light-transmitting layer 320c may include the same organic material as the first light-transmitting layer 320a described above. Alternatively, the third light-transmitting layer 320c may be an inorganic film capable of transmitting light.

The fourth light-blocking layer 310d may be disposed on the third light-transmitting layer 320c. The fourth light-blocking layer 310d may be disposed in the display area of the display panel DP. The fourth light-blocking layer 310d may have the same shape as the third light-blocking layers 310c.

The fourth light-blocking layer 310d may overlap the first conductive layer 202 or the second conductive layer 204 in the third direction. A plurality of fourth light-blocking layers 310d may be disposed to be spaced apart from each other, and some thereof may be disposed to overlap the light-emitting area EA. The fourth light-blocking layer 310d may be disposed to overlap the third light-blocking layer 310c.

The fourth light-blocking layer 310d may block or absorb light emitted from the display panel DP. The fourth light-blocking layer 310d may include a material that blocks or absorbs light. In one or more embodiments, the fourth light-blocking layer 310d may include a light-blocking organic material. The fourth light-blocking layer 310d may include the same material as the first light-blocking layer 310a.

In one or more embodiments, a refractive index of the fourth light-blocking layer 310d may be lower than that of the fourth light-transmitting layer 320d.

The fourth light-transmitting layer 320d may be disposed on the fourth light-blocking layers 310d. The fourth light-transmitting layer 320d may fill openings formed between the fourth light-blocking layers 310d.

The fourth light-transmitting layer 320d may transmit light emitted from the display panel DP. In one or more embodiments, the fourth light-transmitting layer 320d may be an organic film including a transparent organic material capable of transmitting light.

For example, the fourth light-transmitting layer 320d may include the same organic material as the first light-transmitting layer 320a described above. Alternatively, the fourth light-transmitting layer 320d may be an inorganic film capable of transmitting light.

The above-described light-blocking layer 310 may partially absorb light emitted from the light-emitting area EA, thereby limiting a viewing angle of the display device DD.

For example, depending on an angle formed between the third direction, which is perpendicular to the front surface of the display device DD, and light emitted from the light-emitting layer, the light-blocking layer 310 may selectively transmit only a portion of the light and block the remaining light.

That is, depending on the arrangement of the light-blocking layer 310, light emitted obliquely from the light-emitting area EA may be blocked, thereby minimizing or blocking side viewing angles.

In some embodiments, the light-blocking layer 310 may include first light-blocking lines BL1 each disposed in the first direction DR1 and second light-blocking lines BL2 each disposed in the second direction DR2 in a plan view. A detailed description thereof will be provided below.

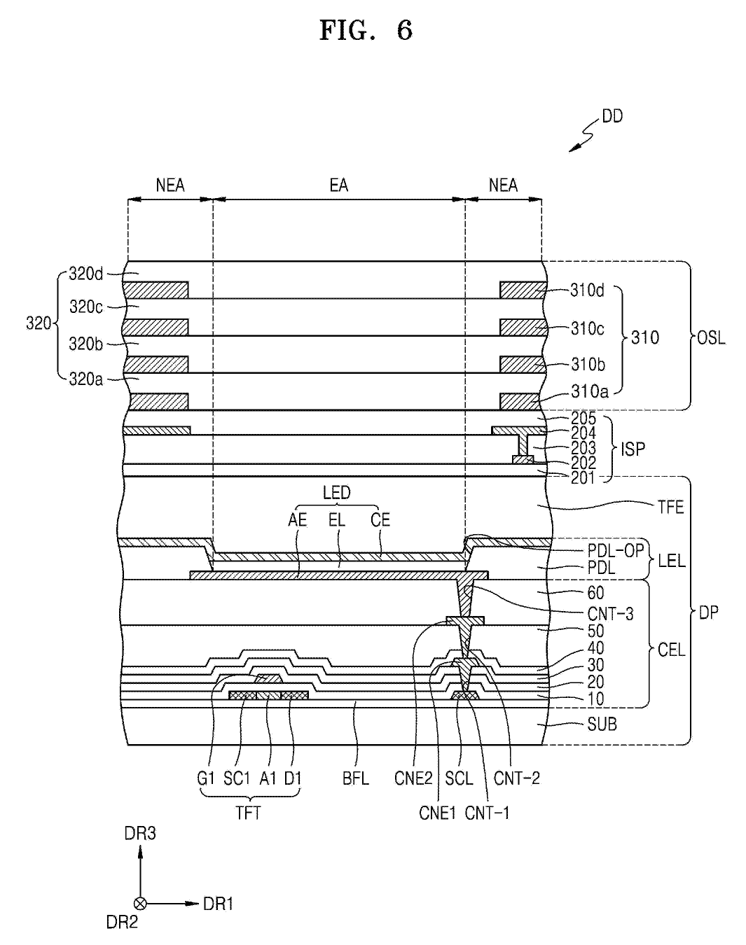

FIG. 6 is a cross-sectional view schematically illustrating a display device DD according to one or more embodiments of the present disclosure.

Referring to FIG. 6, the light control layer OSL of the display device DD according to one or more embodiments may include the light-blocking layer 310 and the light-transmitting layer 320.

Here, the light-blocking layer 310 may include first to fourth light-blocking layers 310a, 310b, 310c, and 310d, and the light-transmitting layer 320 may include first to fourth light-transmitting layers 320a, 320b, 320c, and 320d.

The display device DD according to the present embodiment is substantially identical to the display device DD of FIG. 5 in the corresponding scope, and thus a detailed description thereof will be omitted, and only distinguishing different features will be described.

According to the present embodiment, the first light-blocking layer 310a may be disposed on an input sensor ISP. The first light-blocking layer 310a may be disposed on the first conductive layer 202 or the second conductive layer 204 so as to overlap therewith.

The first light-blocking layer 310a may be formed in a shape corresponding to a pixel-defining film. For example, the first light-blocking layer 310a may be disposed to surround the light-emitting area EA so as not to overlap the light-emitting area EA. Accordingly, a separation distance between the first light-blocking layers 310a may be greater than the opening PDL-OP of the pixel-defining film.

The first light-transmitting layer 320a may be disposed on the first light-blocking layers 310a. The first light-transmitting layer 320a may fill openings formed between the first light-blocking layers 310a.

The second light-blocking layer 310b, the third light-blocking layer 310c, and the fourth light-blocking layer 310d may be disposed on the first light-blocking layer 310a so as to overlap therewith. The second light-transmitting layer 320b may be disposed on the second light-blocking layers 310b. The second light-transmitting layer 320b may fill openings formed between the second light-blocking layers 310b. The third light-transmitting layer 320c may be disposed on the third light-blocking layers 310c. The third light-transmitting layer 320c may fill openings formed between the third light-blocking layers 310c. The fourth light-transmitting layer 320d may be disposed on the fourth light-blocking layers 310d. The fourth light-transmitting layer 320d may fill openings formed between the fourth light-blocking layers 310d.

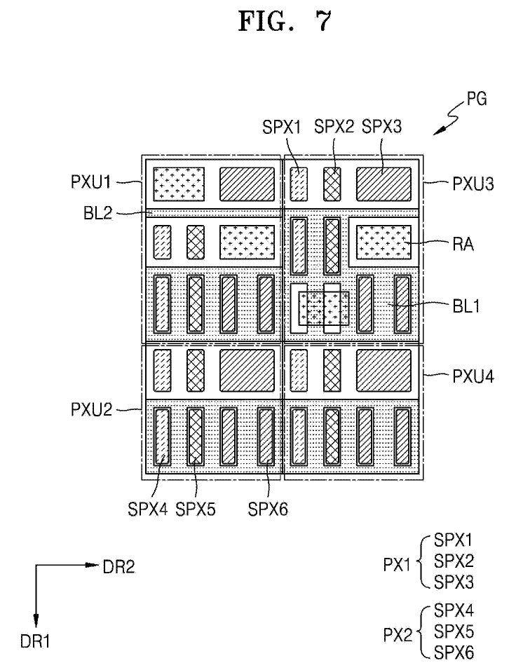

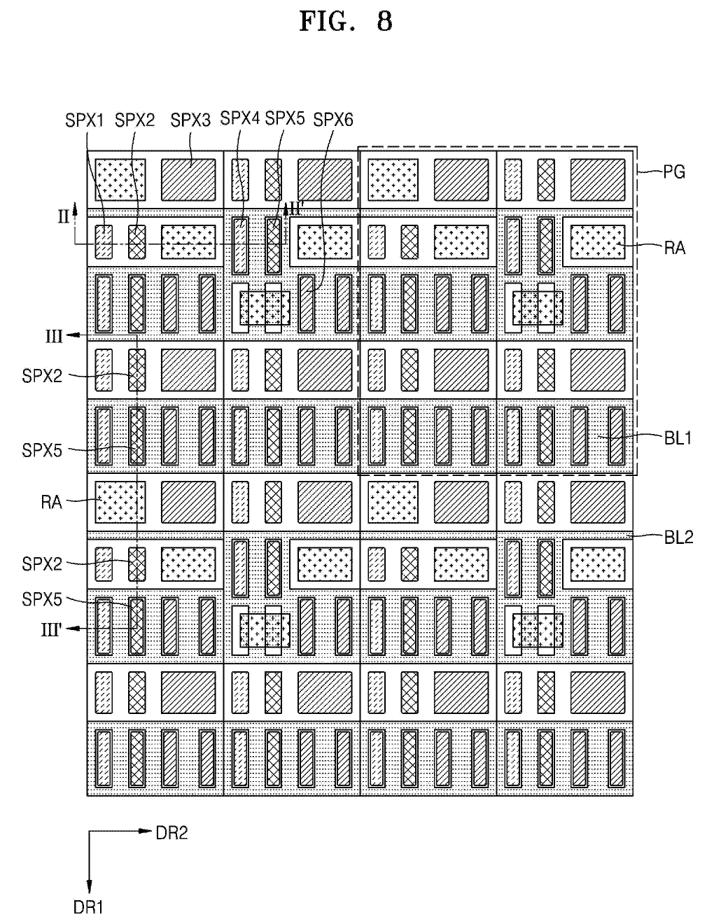

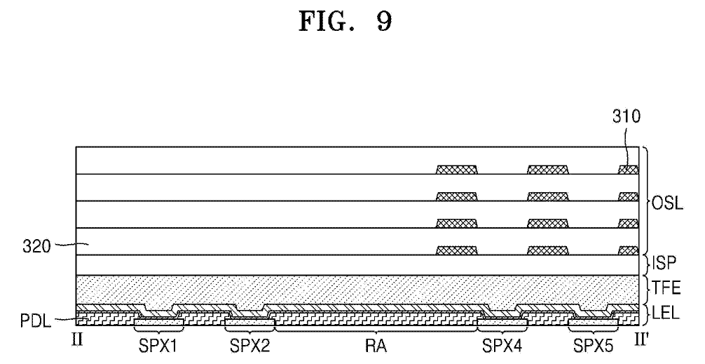

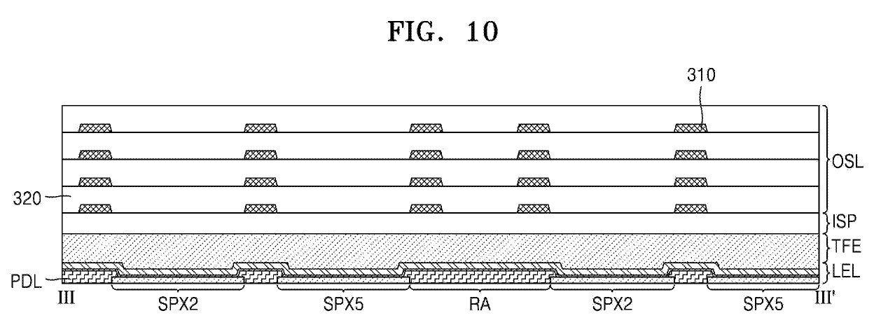

FIG. 7 is an enlarged plan view illustrating a portion of a display device DD according to one or more embodiments of the present disclosure, and FIG. 8 is a plan view illustrating the arrangement of a pixel group PG according to one or more embodiments of the present disclosure. FIG. 9 is a cross-sectional view taken along line II-II′ of FIG. 8, and FIG. 10 is a cross-sectional view taken along line III-III′ of FIG. 8.

Referring to FIGS. 7 and 8, a plurality of pixels may be disposed in a display area DA of the display device DD according to one or more embodiments of the present disclosure. For example, the pixels may be arranged in an array in a first direction DR1 and a second direction DR2 of the display area DA. Each of the pixels may include sub-pixels that emit light of any one of red, green, blue, and white colors. That is, a plurality of sub-pixels may form a single pixel.

In some embodiments, the display device DD according to one or more embodiments of the present disclosure may include pixels that provide different viewing angles. In other words, the pixels may include a plurality of first pixels PX1 and a plurality of second pixels PX2, and each of the first pixels PX1 and the second pixels PX2 may emit light at different viewing angles. Here, each of the first pixels PX1 may emit light at a first viewing angle, and each of the second pixels PX2 may emit light at a second viewing angle that is narrower than the first viewing angle.

The display device DD according to one or more embodiments of the present disclosure may include a first driving mode in which the first pixels PX1 are driven (or configured to be driven) and a second driving mode in which the second pixels PX2 are driven (or configured to be driven). In other words, the display device DD may include two or more driving modes that allow light to be emitted at different viewing angles.

In one or more embodiments, each of the first pixels PX1 may include a first sub-pixel SPX1, a second sub-pixel SPX2, and a third sub-pixel SPX3.

The first sub-pixel SPX1 may be a red sub-pixel that emits red light (R), the second sub-pixel SPX2 may be a green sub-pixel that emits green light (G), and the third sub-pixel SPX3 may be a blue sub-pixel that emits blue light (B). In a light-emitting area EA of each first pixel PX1, light emitted from the first to third sub-pixels SPX1 to SPX3 may be combined and emitted as a final output.

Each of the second pixels PX2 may include a fourth sub-pixel SPX4, a fifth sub-pixel SPX5, and a sixth sub-pixel SPX6.

The fourth sub-pixel SPX4 may be a red sub-pixel that emits red light (R), the fifth sub-pixel SPX5 may be a green sub-pixel that emits green light (G), and the sixth sub-pixel SPX6 may be a blue sub-pixel that emits blue light (B). In a light-emitting area EA of each second pixel PX2, light emitted from the fourth to sixth sub-pixels SPX4 to SPX6 may be combined and emitted as a final output.

The first pixel PX1 and the second pixel PX2 may be disposed adjacent to each other. The first pixel PX1 and the second pixel PX2 adjacent to each other may form a pixel unit.

In other words, the first to sixth sub-pixels SPX1 to SPX6 may form a single unit and may be disposed adjacent to each other.

In one or more embodiments, the display device DD may include two or more pixel units in which the sub-pixels are arranged differently (e.g., in different sequences and/or differently shaped arrangements). For example, referring to FIG. 8, a plurality of pixel units may form the pixel group PG, and the pixel group PG may include a first pixel unit PXU1, a second pixel unit PXU2, and a third pixel unit PXU3, which are configured with different arrangements.

In one or more embodiments, the first pixel unit PXU1 includes the first pixel PX1 and the second pixel PX2, and the fourth sub-pixel SPX4, the fifth sub-pixel SPX5, and the sixth sub-pixel SPX6 of the second pixel PX2 may be sequentially arranged in the second direction DR2. In one or more embodiments, the first light-blocking line BL1 and the second light-blocking line BL2, which are formed of a light-blocking layer, may be disposed near the second pixel PX2.

Here, the first light-blocking line BL1 is a light-blocking pattern disposed in the first direction DR1, and the second light-blocking line BL2 is a light-blocking pattern disposed in the second direction DR2. In other words, the first light-blocking line BL1 and the second light-blocking line BL2 may be disposed to intersect each other.

The first light-blocking line BL1 and the second light-blocking line BL2 may be disposed near the sub-pixels forming the second pixel PX2.

In other words, the first light-blocking line BL1 may be disposed adjacent to the second pixel PX2 in the second direction DR2. In one or more embodiments, the second light-blocking line BL2 may be disposed adjacent to the second pixel PX2 in the first direction DR1.

Accordingly, the second pixel PX2 may have a limited viewing angle due to the light-blocking layer 310 disposed near the second pixel PX2. For example, since the second pixel PX2 is disposed adjacent to the second light-blocking line BL2 in the first direction DR1, the viewing angle may be limited when viewed in a vertical direction based on the drawing. Since the second pixel PX2 is disposed adjacent to the first light-blocking line BL1 in the second direction DR2, the viewing angle may also be limited when viewed in a horizontal direction based on the drawing.

The second light-blocking line BL2 may be disposed near the sub-pixels forming the first pixel PX1. In other words, the second light-blocking line BL2 may be disposed adjacent to the first pixel PX1 in the first direction DR1. For example, the first sub-pixel SPX1 and the second sub-pixel SPX2 of the first pixel unit PXU1 may be disposed adjacent to the second light-blocking line BL2 in the first direction DR1. In other words, the second light-blocking lines BL2 may be disposed in areas above and below the first and second sub-pixels SPX1 and SPX2 in the drawing. Accordingly, since the first pixels PX1 is disposed adjacent to the second light-blocking line BL2 in the first direction DR1, the viewing angle may be limited when viewed in the vertical direction based on the drawing.

However, the first light-blocking line BL1 may not be disposed near the first pixel PX1. In other words, the first light-blocking line BL1 may not be disposed adjacent to the first pixel PX1 in the second direction DR2. That is, the first sub-pixel SPX1, the second sub-pixel SPX2, and the third sub-pixel SPX3 may not be adjacent to the first light-blocking line BL1 in the second direction DR2.

Referring to FIGS. 7 and 9, the first sub-pixel SPX1, the second sub-pixel SPX2, a rib area RA, the fourth sub-pixel SPX4, and the fifth sub-pixel SPX5 may be sequentially arranged in the second direction DR2.

Here, it may be confirmed that no light-blocking layer is disposed in the light control layer OSL disposed over the first sub-pixel SPX1 and the second sub-pixel SPX2, whereas the light-blocking layer is disposed in the light control layer OSL disposed over the fourth sub-pixel SPX4 and the fifth sub-pixel SPX5.

Accordingly, since the light-blocking layers are disposed near the fourth sub-pixel SPX4 and the fifth sub-pixel SPX5, the viewing angle of light emitted from the light-emitting area EA may be limited.

In one or more embodiments, since no light-blocking layer is disposed near the first pixel PX1, such as the first sub-pixel SPX1 and the second sub-pixel SPX2, the first pixel PX1 may provide a wider viewing angle compared to the second pixel PX2.

Referring to FIGS. 7 and 10, the second sub-pixel SPX2, the fifth sub-pixel SPX5, the rib area RA, the second sub-pixel SPX2, and the fifth sub-pixel SPX5 may be sequentially arranged in the first direction DR1.

Here, the light-blocking layer may be disposed in the light control layer OSL disposed over the fifth sub-pixel SPX5. For example, the second light-blocking line BL2 may be disposed near the fifth sub-pixel SPX5.

The light-blocking layer may also be disposed in the light control layer OSL disposed over the second sub-pixel SPX2. For example, the second light-blocking line BL2 may be disposed near the second sub-pixel SPX2.

Accordingly, since the second light-blocking line BL2 is disposed near the second sub-pixel SPX2 of the first pixel PX1, the viewing angle in the first direction DR1 may be reduced. However, the concept of the present disclosure is not limited thereto, and the second light-blocking line BL2 may not be disposed near the first pixel PX1.

The first pixel PX1 may be disposed adjacent to another first pixel PX1 in the second direction DR2. The first pixel PX1 may also be disposed adjacent to the rib area RA in the second direction DR2. That is, the rib area RA may be disposed adjacent to the first pixel PX1.

Here, the rib area RA corresponds to a rib portion RP of the mask sheet 510 and is an area where no pixels are disposed.

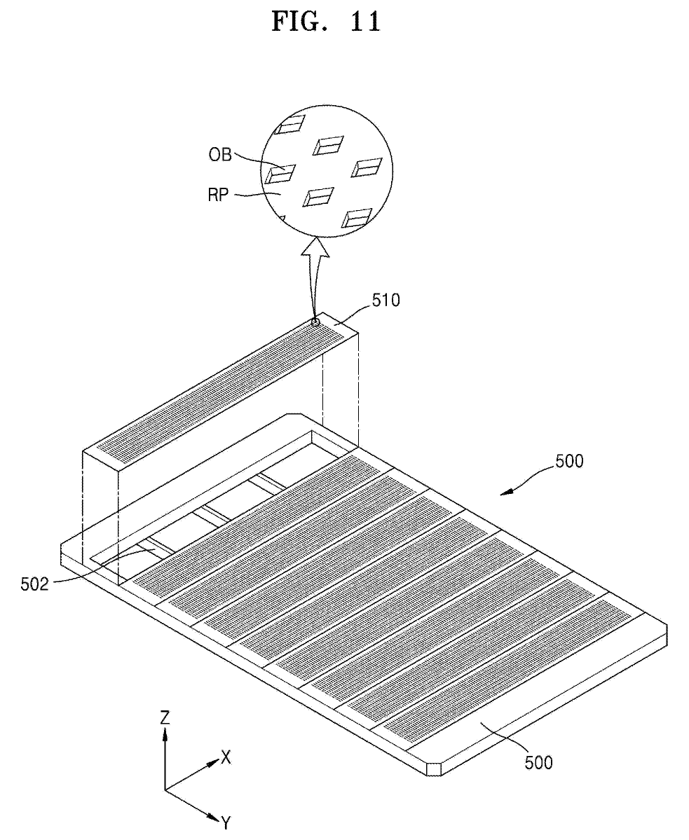

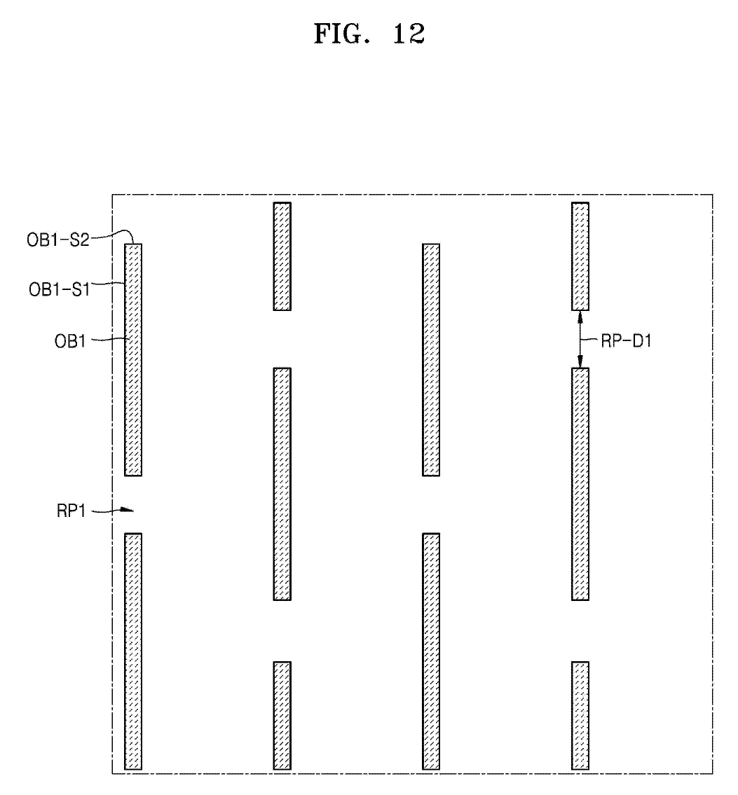

FIG. 11 is a perspective view schematically illustrating a mask assembly for thin film deposition according to one or more embodiments of the present disclosure FIGS. 12 to 14 are enlarged plan views each illustrating a portion of a mask sheet according to one or more embodiments of the present disclosure.

An organic material layer serving as an light-emitting layer EL of the light-emitting element LED may be formed as a film on the substrate using an organic material deposition apparatus capable of depositing a target material. The organic material deposition apparatus uses a mask to form an intended shape of an organic film on the substrate. A metal mask having a high level of durability and strength may be used to reliably deposit an organic material in an intended pattern.

A fine metal mask (FMM) is a mask used to deposit an organic material in a fine pattern onto a large substrate.

Referring to FIG. 11, a mask assembly 500 may include a mask frame 501, a mask sheet 510, and a support frame 502.

The mask frame 501 may have an opening formed at its center. In such a case, the mask frame 501 may be formed in a shape similar to a window frame. In another embodiment, the mask frame 501 may have an opening formed at its center, and a separate frame dividing the opening in a grid pattern may be disposed in the opening. For convenience of description, the following description will focus on a case in which the mask frame 501 has a single opening formed at its center.

The mask sheet 510 may be disposed on one surface of the mask frame 501 while being tensioned in at least one of the first direction DR1 and the second direction DR2, and may be fixed to the mask frame 501 by welding or the like. The mask sheet 510 may be formed in a rectangular shape and disposed along one side of the mask frame 501. The mask sheet 510 may also be formed in a slit shape.

A plurality of mask sheets 510 may be provided. In this case, the plurality of mask sheets 510 may be arranged in a row to be adjacent to each other in the first direction DR1 or the second direction DR2.

Each of the mask sheets 510 may have a plurality of openings OB. In this case, the plurality of openings OB may be arranged to be spaced apart from each other in the first direction DR1 and the second direction DR2.

Each of the openings OB may be formed in a rectangular shape elongated in a direction in which the mask sheet 510 is tensioned. The plurality of openings OB may be formed to correspond to one or more of the above-described sub-pixel arrangements.

FIG. 12 is an enlarged plan view of a partial area of a first mask sheet for arranging the first sub-pixel SPX1 and the fourth sub-pixel SPX4.

Referring to FIG. 12, the first mask sheet may include first openings OB1, each of which may be formed in a rectangular shape surrounded by a first side OB1-S1 and a second side OB1-S2 having different lengths.

In one or more embodiments, the first openings OB1 may be arranged in the first direction DR1 or the second direction DR2 of the first mask sheet. A length of the first side OB1-S1 of the first opening OB1 may be greater than a length of the second side OB1-S2.

In one or more embodiments, another first opening OB1 may be formed at a certain distance apart from the first opening OB1 in a length direction of the first side OB1-S1. Here, a separation space between the first openings OB1 arranged in the length direction of the first side OB1-S1 may be referred to as a rib portion RP1. That is, a distance between the first openings OB1 arranged in the length direction of the first side OB1-S1 may be defined as a length RP-D1 of the rib portion RP1.

Another first opening OB1 may be disposed to be spaced apart from the first opening OB1 in a length direction of the second side OB1-S2. In this case, the distance between the first openings OB1 may be greater than the length of the second side OB1-S2.

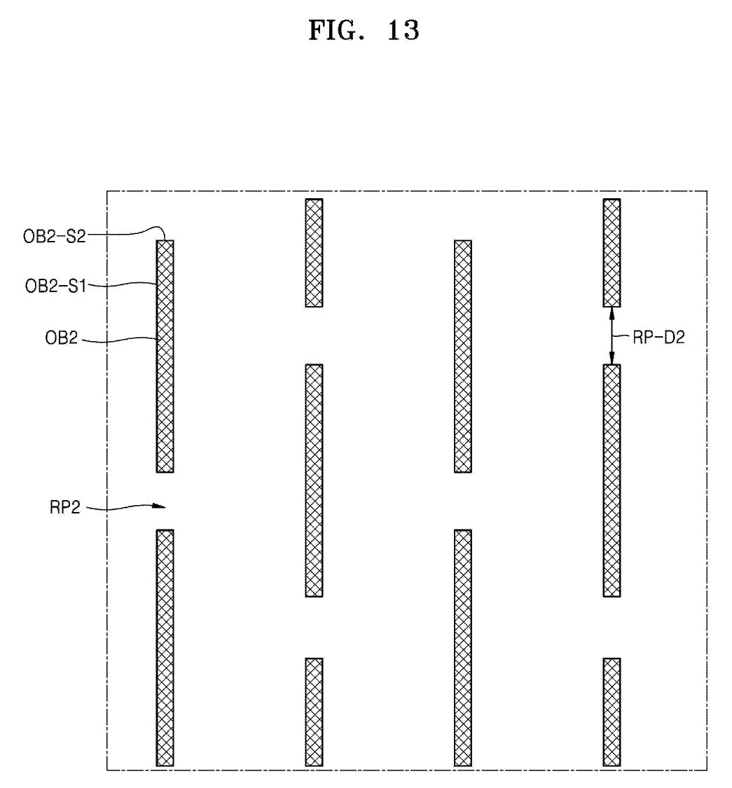

FIG. 13 is an enlarged plan view of a partial area of a second mask sheet for arranging the second sub-pixel SPX2 and the fifth sub-pixel SPX5.

Referring to FIG. 13, the second mask sheet may include second openings OB2, each of which may be formed in a rectangular shape surrounded by a first side OB2-S1 and a second side OB2-S2 having different lengths.

In one or more embodiments, the second openings OB2 may be arranged in the first direction DR1 or the second direction DR2 of the second mask sheet. A length of the first side OB2-S1 of the second opening OB2 may be greater than a length of the second side OB2-S2.

In one or more embodiments, another second openings OB2 may be formed at a certain distance apart from the second openings OB2 in a length direction of the first side OB2-S1. Here, a separation space between the second openings OB2 arranged in the length direction of the first side OB2-S1 may be referred to as a rib portion RP2. That is, a distance between the second openings OB2 arranged in the length direction of the first side OB2-S1 may be defined as a length RP-D2 of the rib portion RP2.

Another second opening OB2 may be disposed to be spaced apart from the second opening OB2 in a length direction of the second side OB2-S2. In this case, the distance between the second openings OB2 may be greater than the length of the second side OB2-S2.

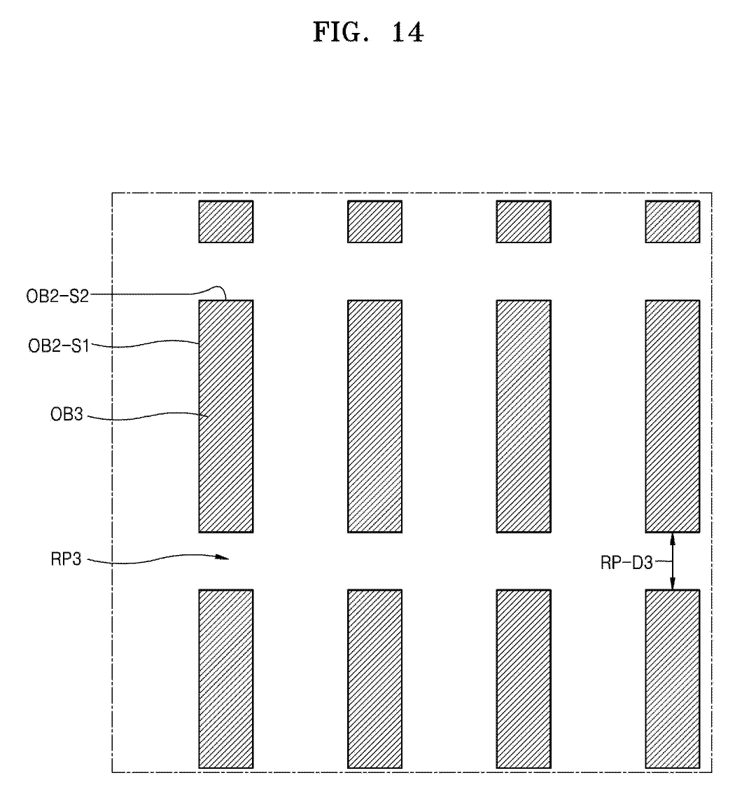

FIG. 14 is an enlarged plan view of a partial area of a third mask sheet for arranging the third sub-pixel SPX3 and the sixth sub-pixel SPX6.

Referring to FIG. 14, the third mask sheet may include third openings OB3, each of which may be formed in a rectangular shape surrounded by a first side OB3-S1 and a second side OB3-S2 having different lengths.

In one or more embodiments, the third openings OB3 may be arranged in the first direction DR1 or the second direction DR2 of the third mask sheet. A length of the first side OB3-S1 of the third opening OB3 may be greater than a length of the second side OB3-S2.

In one or more embodiments, another third opening OB3 may be formed at a certain distance apart from the third opening OB3 in a length direction of the first side OB3-S1. Here, a separation space between the third openings OB3 arranged in the length direction of the first side OB3-S1 may be referred to as a rib portion RP3. That is, a distance between the third openings OB3 arranged in the length direction of the first side OB3-S1 may be defined as a length RP-D2 of the rib portion RP3.

Another third opening OB3 may be disposed to be spaced apart from the third opening OB3 in a length direction of the second side OB3-S2. In this case, the distance between the third openings OB3 may be greater than the length of the second side OB3-S2.

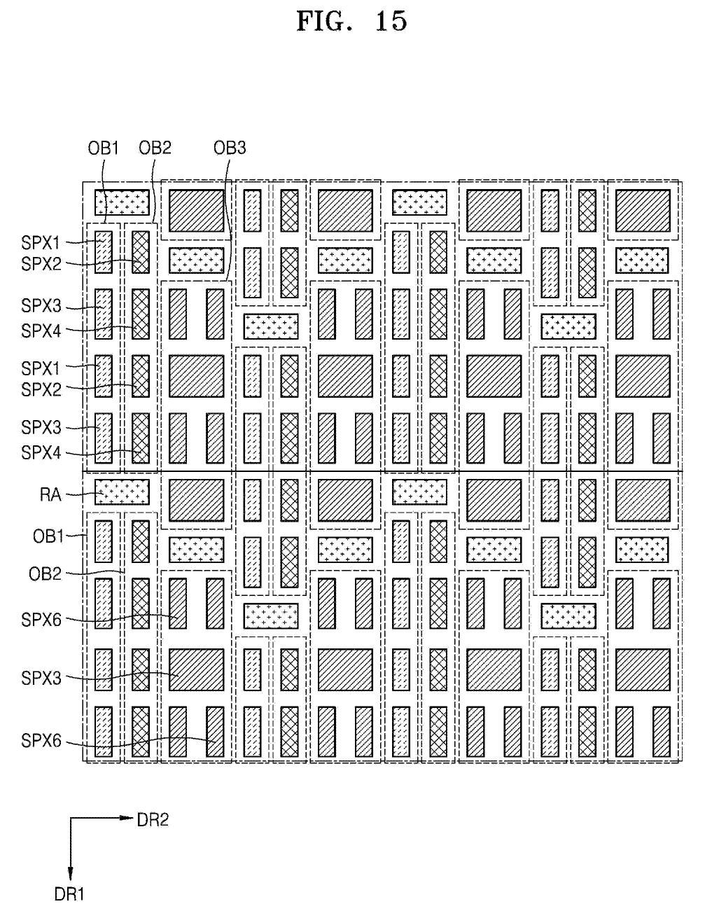

FIG. 15 is an enlarged plan view illustrating a portion of the display device DD according to one or more embodiments of the present disclosure. FIG. 15 is a plan view collectively illustrating the openings of the mask sheets, which correspond to the respective pixels shown in FIG. 7. Here, the illustration of the light-blocking layer is omitted.

Referring to FIGS. 7 and 15, the first opening OB1 of the first mask sheet, the second opening OB2 of the second mask sheet, and the third opening OB3 of the third mask sheet may be disposed side by side.

The rib area RA is an area corresponding to the rib portion RP formed between the openings OB. In one or more embodiments, the rib areas RA corresponding to the rib portion RP1 formed between the first openings OB1 and the rib portion RP2 formed between the second openings OB2 may be present. In one or more embodiments, the rib area RA corresponding to the rib portion RP3 formed between the third openings OB3 may be present.

Conventionally, the rib area RA has been disposed for each pixel unit. That is, one rib area RA was present for each first pixel PX1 and each second pixel PX2. However, as the number of rib areas RA increases, an aperture ratio decreases, which adversely affects the lifespan of the display. The aperture ratio may refer to the ratio of a light-emitting area of a pixel to the total area of the pixel. To address this issue, a structure in which one rib area RA is present for every two pixel units has been adopted. However, in such a structure, lateral visibility of the first pixel PX1 may be degraded due to the light-blocking layer. Alternatively, a significant color shift occurred depending on the viewing angle, thereby degrading the display quality.

The present disclosure is intended to solve the above-described issues, and by changing the arrangement of the rib area RA and the respective sub-pixels, the area of the rib area RA may be reduced, and issues such as the lateral visibility of the first pixel PX1 and the color shift depending on the viewing angle may be improved.

Referring again to FIG. 7, the first pixel unit PXU1 may include the rib area RA disposed adjacent to the first sub-pixel SPX1, the second sub-pixel SPX2, and the third sub-pixel SPX3. That is, the first pixel PX1 of the first pixel unit PXU1 may be disposed adjacent to the rib area RA.

The second pixel unit PXU2 may include the rib area RA disposed adjacent to the fourth sub-pixel SPX4, the fifth sub-pixel SPX5, and the sixth sub-pixel SPX6. That is, the second pixel PX2 of the second pixel unit PXU2 may be disposed adjacent to the rib area RA.

In one or more embodiments, the third pixel unit PXU3 may include only the first pixel PX1 and the second pixel PX2, and may not include the rib area RA. A fourth pixel unit PXU4 may have the same sub-pixel arrangement as the third pixel unit PXU3.

As shown in FIG. 8, the first pixels PX1, the second pixels PX2, and the rib areas RA may be arranged in a predetermined pattern to form the pixel group PG.

In one or more embodiments, the rib areas RA may be discontinuously arranged in the first direction DR1 and the second direction DR2. In one or more embodiments, the rib areas RA may be alternately staggered to be arranged in a zigzag pattern in the second direction DR2.

Referring again to FIG. 7, the pixel group PG may be repeatedly disposed in the first direction DR1 and the second direction DR2. In the pixel group PG, the first pixel PX1 and the second pixel PX2 may be alternately disposed in the first direction DR1.

In one or more embodiments, the first pixel unit PXU1 and the second pixel unit PXU2 may be alternately disposed in the first direction DR1, the first pixel unit PXU1 and the third pixel unit PXU3 may be alternately disposed in the second direction DR2, and the third pixel unit PXU3 and the fourth pixel unit PXU4 may be alternately disposed in the first direction DR1.

The first pixel PX1 may include the first to third sub-pixels SPX1 to SPX3 that emit different colors, and the second pixel PX2 may include the fourth to sixth sub-pixels SPX4 to SPX6 that emit different colors.

Here, in the first pixel unit PXU1, the rib area RA, the first pixel PX1, and the second pixel PX2 may be sequentially arranged in the first direction DR1, or the first pixel PX1, the rib area RA, and the second pixel PX2 may be sequentially arranged in the first direction DR1.

For example, in the first pixel unit PXU1, the rib area RA, the first sub-pixel SPX1, and the fourth sub-pixel SPX4 may be sequentially arranged in the first direction DR1. For example, in the first pixel unit PXU1, the rib area RA, the second sub-pixel SPX2, and the fifth sub-pixel SPX5 may be sequentially arranged in the first direction DR1. For example, in the first pixel unit PXU1, the third sub-pixel SPX3, the rib area RA, and the sixth sub-pixel SPX6 may be sequentially arranged in the first direction DR1.

In the third pixel unit PXU3, the first pixel PX1, the second pixel PX2, and the rib area RA may be sequentially arranged in the first direction DR1, or the first pixel PX1, the rib area RA, and the second pixel PX2 may be sequentially arranged in the first direction DR1.

For example, in the third pixel unit PXU3, the first sub-pixel SPX1, the fourth sub-pixel SPX4, and the rib area RA may be sequentially arranged in the first direction DR1. For example, in the third pixel unit PXU3, the second sub-pixel SPX2, the fifth sub-pixel SPX5, and the rib area RA may be sequentially arranged in the first direction DR1. For example, in the third pixel unit PXU3, the third sub-pixel SPX3, the rib area RA, and the sixth sub-pixel SPX6 may be sequentially arranged in the first direction DR1.

In each of the second pixel unit PXU2 and the fourth pixel unit PXU4, the first sub-pixel SPX1 and the fourth sub-pixel SPX4 may be sequentially arranged in the first direction DR1. For example, in each of the second pixel unit PXU2 and the fourth pixel unit PXU4, the second sub-pixel SPX2 and the fifth sub-pixel SPX5 may be sequentially arranged in the first direction DR1. For example, the third sub-pixel SPX3 and the sixth sub-pixel SPX6 may be sequentially arranged in the first direction DR1.

In the display area DA, the first sub-pixel SPX1, the second sub-pixel SPX2, the rib area RA, the fourth sub-pixel SPX4, the fifth sub-pixel SPX5, and the rib area RA may be sequentially arranged as a whole in the second direction DR2. For example, the rib area RA, the third sub-pixel SPX3, the first sub-pixel SPX1, the second sub-pixel SPX2, and the third sub-pixel SPX3 may be sequentially arranged in the second direction DR2. For example, the fourth sub-pixel SPX4, the fifth sub-pixel SPX5, the rib area RA, and the sixth sub-pixel SPX6 may be sequentially arranged in the second direction DR2.

With such an arrangement, the rib areas RA may be discontinuously arranged in the second direction DR2, and the first light-blocking line BL1 may not be directly adjacent to the first pixel PX1.

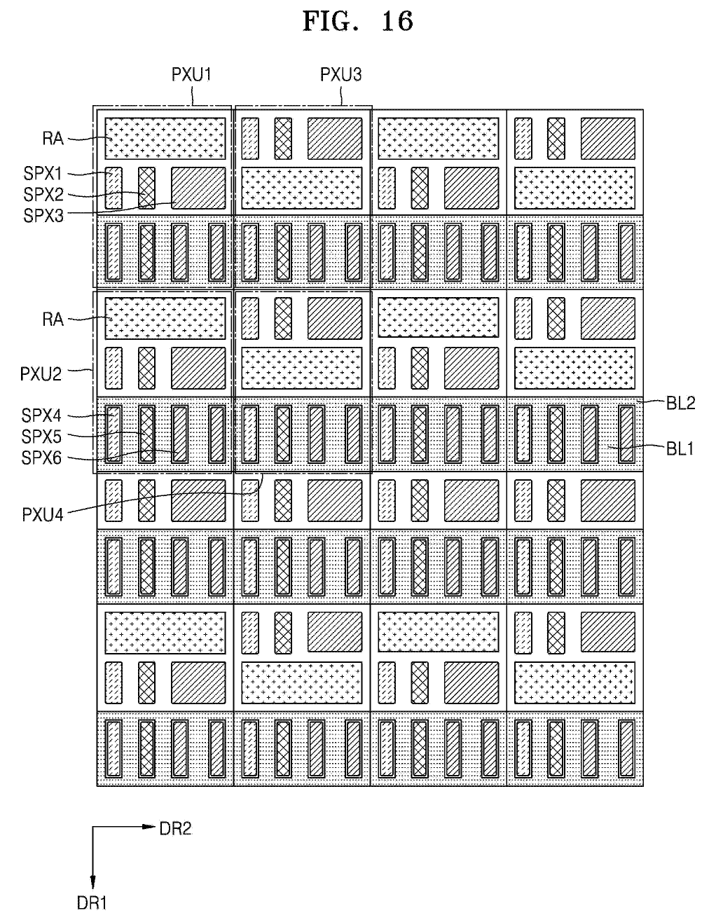

FIG. 16 is an enlarged plan view illustrating a portion of the display device DD according to one or more embodiments of the present disclosure.

Referring to FIG. 16, in the first pixel unit PXU1, the rib area RA, the first pixel PX1, and the second pixel PX2 may be sequentially arranged in the first direction DR1, and in the third pixel unit PXU3, the first pixel PX1, the rib area RA, and the second pixel PX2 may be sequentially arranged in the first direction DR1.

For example, in the first pixel unit PXU1, the rib area RA, the first sub-pixel SPX1, and the fourth sub-pixel SPX4 may be sequentially arranged in the first direction DR1. For example, the rib area RA, the second sub-pixel SPX2, and the fifth sub-pixel SPX5 may be sequentially arranged in the first direction DR1. For example, the rib area RA, the third sub-pixel SPX3, and the sixth sub-pixel SPX6 may be sequentially arranged in the first direction DR1.

In the third pixel unit PXU3, the first sub-pixel SPX1, the rib area RA, and the fourth sub-pixel SPX4 may be sequentially arranged in the first direction DR1. For example, the second sub-pixel SPX2, the rib area RA, and the fifth sub-pixel SPX5 may be sequentially arranged in the first direction DR1. For example, the third sub-pixel SPX3, the rib area RA, and the sixth sub-pixel SPX6 may be sequentially arranged in the first direction DR1.

In the display area DA, the first pixel PX1, the rib area RA, and the first pixel PX1 may be sequentially arranged as a whole in the second direction DR2. For example, the second pixels PX2 may be continuously arranged in the second direction DR2.

With such an arrangement, the rib areas RA may be discontinuously arranged in the second direction DR2, and the first light-blocking line BL1 may not be directly adjacent to the first pixel PX1.

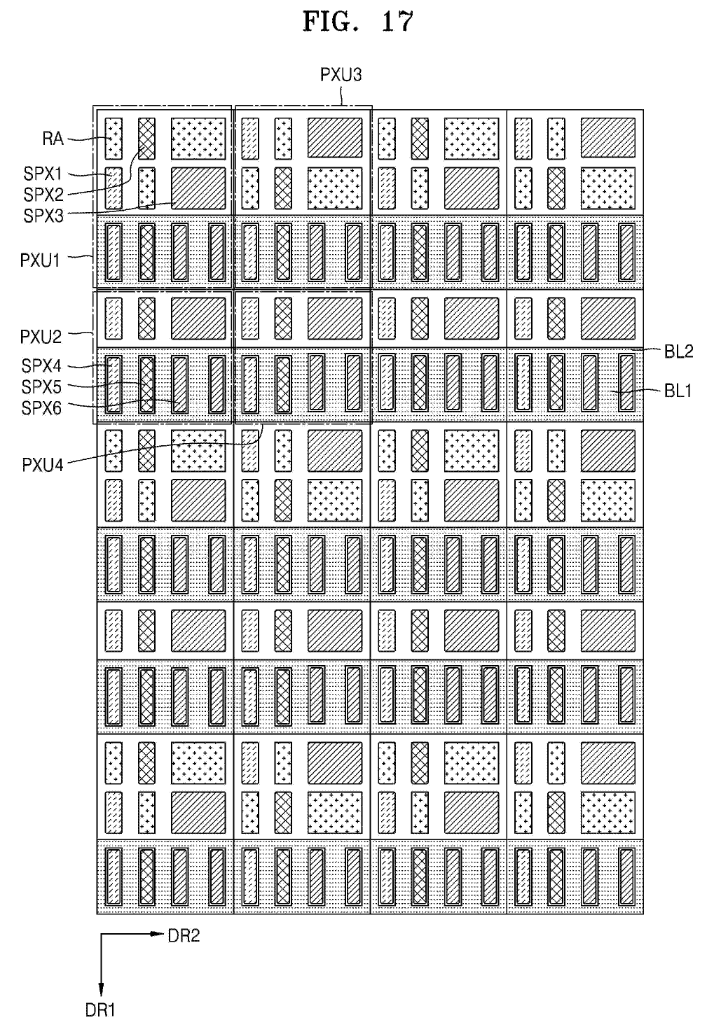

FIG. 17 is an enlarged plan view illustrating a portion of the display device DD according to one or more embodiments of the present disclosure.

Referring to FIG. 17, in the first pixel unit PXU1 and the third pixel unit PXU3, the sequence in which the first sub-pixel SPX1, the second sub-pixel SPX2 and the rib areas RA are arranged in the first direction DR1 may be different for the first pixel unit PXU1 and the third pixel unit PXU3.

For example, in each of the first pixel unit PXU1 and the third pixel unit PXU3, the first pixel PX1, and the second pixel PX2 may be sequentially arranged in the first direction DR1, or the first pixel PX1, the rib area RA, and the second pixel PX2 may be sequentially arranged in the first direction DR1.

For example, in the first pixel unit PXU1, the rib area RA, the first sub-pixel SPX1, and the fourth sub-pixel SPX4 may be sequentially arranged in the first direction DR1, the second sub-pixel SPX2, the rib area RA, and the fifth sub-pixel SPX5 may be sequentially arranged in the first direction DR1, and the rib area RA, the third sub-pixel SPX3, and the sixth sub-pixel SPX6 may be sequentially arranged in the first direction DR1.

In the third pixel unit PXU3, the first sub-pixel SPX1, the rib area RA, and the fourth sub-pixel SPX4 may be sequentially arranged in the first direction DR1, the rib area RA, the second sub-pixel SPX2, and the fifth sub-pixel SPX5 may be sequentially arranged in the first direction DR1, and the third sub-pixel SPX3, the rib area RA, and the sixth sub-pixel SPX6 may be sequentially arranged in the first direction DR1.

In the display area DA, the first sub-pixel SPX1, the rib area RA, the third sub-pixel SPX3, the rib area RA, and the second sub-pixel SPX2 may be sequentially arranged as a whole in the second direction DR2.

With such an arrangement, the rib areas RA may be discontinuously arranged in the second direction DR2, and the first light-blocking line BL1 may not be directly adjacent to the first pixel PX1.

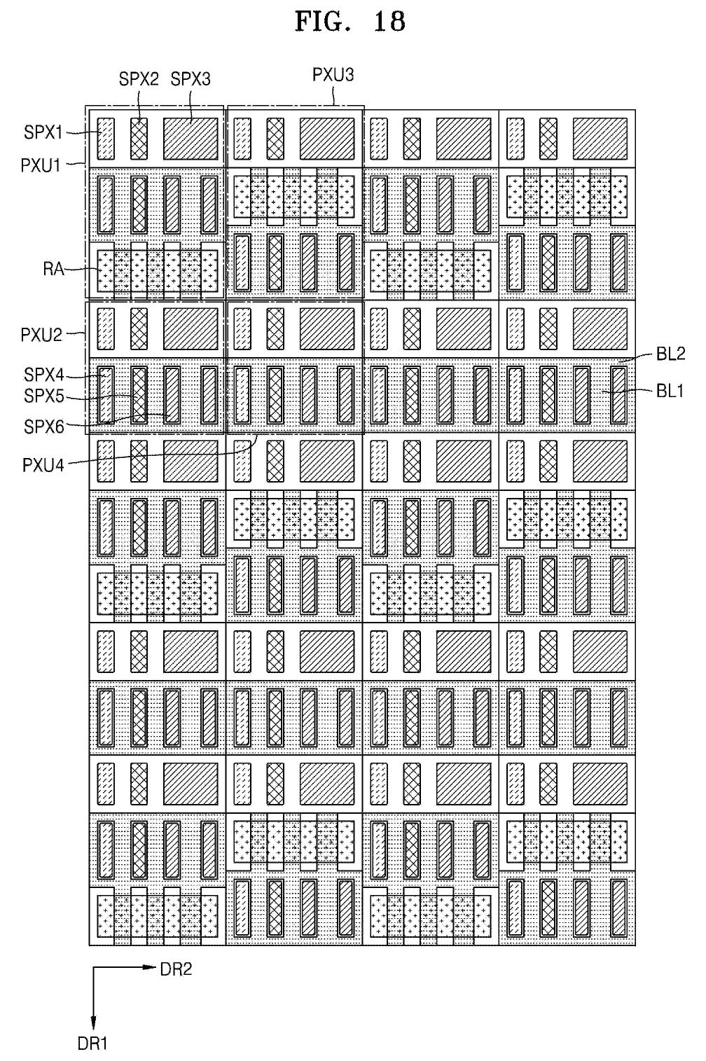

FIG. 18 is an enlarged plan view illustrating a portion of the display device DD according to one or more embodiments of the present disclosure.

Referring to FIG. 18, in the first pixel unit PXU1, the first pixel PX1, the second pixel PX2, and the rib area RA may be sequentially arranged in the first direction DR1.

For example, in the first pixel unit PXU1, the first sub-pixel SPX1, the fourth sub-pixel SPX4, and the rib area RA may be sequentially arranged in the first direction DR1, the second sub-pixel SPX2, the fifth sub-pixel SPX5, and the rib area RA may be sequentially arranged in the first direction DR1, and the third sub-pixel SPX3, the sixth sub-pixel SPX6, and the rib area RA may also be sequentially arranged in the first direction DR1.

In the third pixel unit PXU3, the first pixel PX1, the rib area RA, and the second pixel PX2 may be sequentially arranged in the first direction DR1.

For example, in the third pixel unit PXU3, the first sub-pixel SPX1, the rib area RA, and the fourth sub-pixel SPX4 may be sequentially arranged in the first direction DR1, the second sub-pixel SPX2, the rib area RA, and the fifth sub-pixel SPX5 may be sequentially arranged in the first direction DR1, and the third sub-pixel SPX3, the rib area RA, and the sixth sub-pixel SPX6 may be sequentially arranged in the first direction DR1.

In the display area DA, the second pixel PX2, the rib area RA, and the second pixel PX2 may be sequentially arranged in the second direction DR2. In one or more embodiments, the first pixels PX1 may be continuously arranged in the second direction DR2.

For example, in each of the first pixel unit PXU1 and the third pixel unit PXU3, the fourth sub-pixel SPX4, the fifth sub-pixel SPX5, the sixth sub-pixel SPX6 and the rib area RA may be sequentially arranged in the second direction DR2.

With such an arrangement, the rib areas RA may be discontinuously arranged in the second direction DR2, and the first light-blocking line BL1 may not be directly adjacent to the first pixel PX1.

The display device according to the embodiment may be applied to various electronic devices. The electronic device according to one or more embodiments may include the display device described above and may further include modules or devices having additional functions other than the display device.

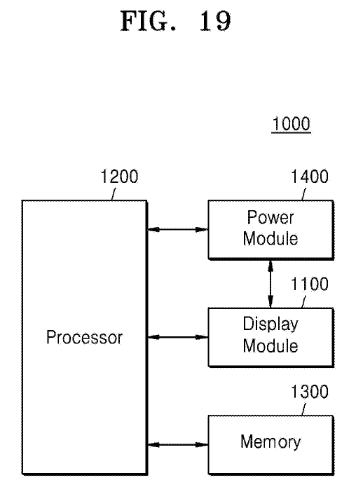

FIG. 19 is a block diagram of an electronic device according to one or more embodiments. Referring to FIG. 19, an electronic device 1000 according to one or more embodiments may include a display module 1100, at least one processor 1200, a memory 1300, and a power module 1400.

The at least one processor 1200 may include at least one of a central processing unit (CPU), an application processor (AP), a graphic processing unit (GPU), a communication processor (CP), an image signal processor (ISP), and a controller. In one or more embodiments, the at least one processor 1200 may be provided in a form divided into two or more parts from a functional or structural perspective. For example, the at least one processor 1200 may include a main processor in the form of a first driving chip including a central processing unit, and a sub-processor in the form of a second driving chip including a controller configured to receive a video signal from the main processor and process the video signal to comply with interface specifications of the display module 1100.

The memory 1300 may include at least one of a non-volatile memory and a volatile memory. The memory 1300 may store data information necessary for the operation of the at least one processor 1200 or the display module 1100. When the at least one processor 1200 executes an application stored in the memory 1300, a video data signal and/or an input control signal may be transmitted to the display module 1100, and the display module 1100 may process the received signal and output video information through a display screen.

The power module 1400 may include a power supply module, such as a power adapter or a battery device, and a power conversion module that converts power supplied by the power supply module to generate power required for the operation of the electronic device 1000. The power conversion by the power conversion module may include direct current-to-direct current (DC-DC) conversion, alternating current-to-direct current (AC-DC) conversion, or direct current-to-alternating current (DC-AC) conversion, but the present disclosure is not limited thereto.

At least one of the components of the electronic device 1000 described above may be included in the display device according to the embodiments described above. In addition, a portion of individual modules included functionally in one module may be included in the display device, while another portion thereof may be provided separately from the display device. For example, the display device may include the display module 1100 and a sub-processor of the at least one processor 1200, while a main processor of the at least one processor 1200, the memory 1300, and the power module 1400 may be provided in the form of separate components within the electronic device 1000, rather than within the display device. As another example, the power module 1400 may be provided within the display device and may supply power to the at least one processor 1200 and the memory 1300 provided within the electronic device 1000, rather than within the display device, without being limited to the above examples.

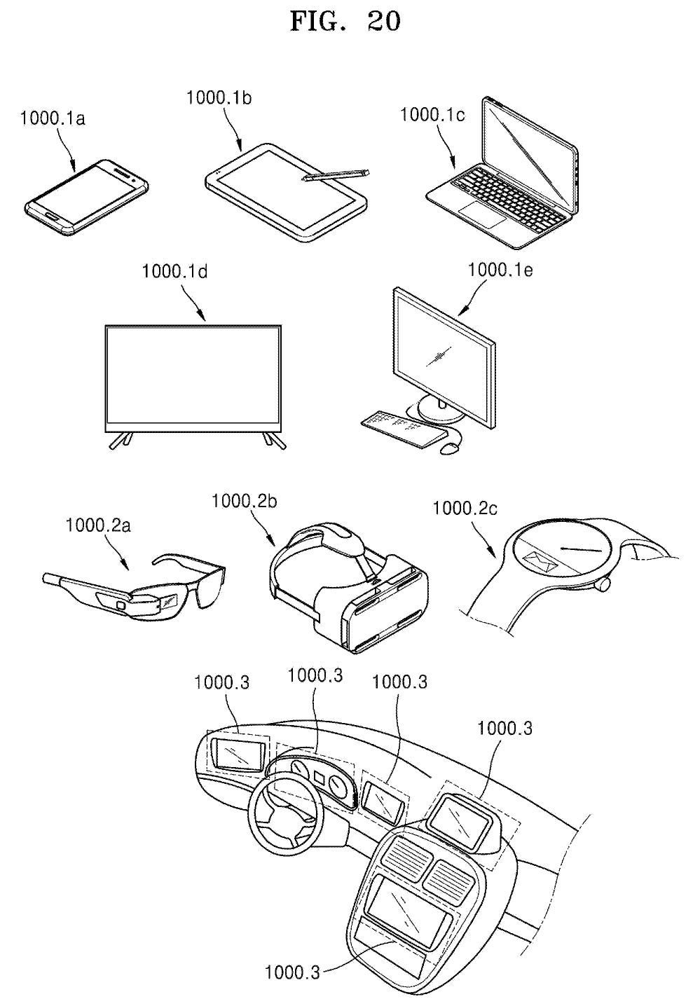

FIG. 20 is a set of schematic views of electronic devices according to various embodiments.

Referring to FIG. 20, various electronic devices to which the display device according to the embodiments is applied may include not only image display electronic devices such as a smartphone 1000_1a, a tablet personal computer (PC) 1000_1b, a laptop computer 1000_1c, a TV 1000_1d, and a desktop monitor 1000_1e, but also wearable electronic devices including a display module, such as smart glasses 1000_2a, a head-mounted display 1000_2b, and a smart watch 1000_2c, and vehicle electronic devices 1000_3 including a display module, such as an instrument cluster, a center fascia, a center information display (CID) disposed on a dashboard, and a room mirror display.

The electronic devices illustrated in FIG. 20 may include the components illustrated in FIG. 19. For example, the smartphone 1000_1a may include the display module 1100, the at least one processor 1200, the memory 1300, and the power module 1400 illustrated in FIG. 19. The smartphone 1000_1a may further include a communication module and a battery device. Power supplied from the battery device may be converted by the power module 1400 and provided to the processor 1200, the memory 1300, and the display module 1100. In one or more embodiments, the display device applied to the smartphone 1000_1a may include the display module 1100 and may further include the power module 1400. The at least one processor 1200 and the memory 1300 may be provided in the form of chips mounted on a motherboard, which is an external device, but the present disclosure is not limited thereto.

Each of the embodiments described above can be implemented independently, but the structures of the embodiments can also be combined and applied to other embodiments.

According to one or more embodiments of the present disclosure, a display device can be provided, which includes pixels supporting modes for implementing different viewing angles, thereby improving visibility and realizing high-quality images.

However, the above effect is exemplary, and the effects of the present disclosure are not limited thereto.

The present disclosure has been described with reference to the embodiments illustrated in the drawings, but these are only examples. It will be understood by those skilled in the art that various modifications and equivalent other embodiments may be made. Accordingly, the true technical scope of the present disclosure is defined by the technical spirit of the appended claims.

The particular implementations shown and described herein are illustrative examples of the embodiments and are not intended to otherwise limit the scope of the embodiments in any way. In addition, no item or element is essential to the practice of the present disclosure unless the element is specifically described as “essential” or “critical.”

The use of the terms “a” and “an” and “the” and similar referents in the context of describing the present disclosure (especially in the context of the following claims) are to be construed to cover both the singular and the plural. Further, recitation of ranges of values herein are merely intended to serve as a shorthand method of referring individually to each separate value falling within the range, unless otherwise indicated herein, and each separate value is incorporated into the specification as if it were individually recited herein. Finally, operations of all methods described herein can be performed in any suitable order unless otherwise indicated herein or otherwise clearly contradicted by context. The present disclosure is not necessarily limited to the described order of the operations. The use of any and all examples, or exemplary terms provided herein, is intended merely to better illustrate the embodiments and does not pose a limitation on the scope of the embodiments unless otherwise claimed. In addition, it would be apparent to those of ordinary skill in the art that various modifications and changes may be easily made without departing from the scope and spirit of the present disclosure.

What is claimed is:

1. A display device comprising:
a display panel comprising a first pixel having a first viewing angle and a second pixel having a second viewing angle narrower than the first viewing angle, the first pixel and the second pixel in a display area; and
a light control layer configured to control a path of light, the light control layer comprising a light-blocking layer on the display panel,
wherein the display area comprises a rib area in an area other than a light-emitting area,
wherein the first pixel, the second pixel, and the rib area are arranged in a predetermined pattern to form a pixel group, and
wherein the rib area is arranged repeatedly and discontinuously in a first direction and in a second direction intersecting the first direction.

2. The display device of claim 1, wherein the light-blocking layer comprises a first light-blocking line extending in the first direction and a second light-blocking line extending in the second direction.

3. The display device of claim 2, wherein, in the second direction, the first light-blocking line is adjacent to the second pixel, but not to the first pixel.

4. The display device of claim 3, wherein the second light-blocking line is adjacent to the first pixel and the second pixel in the first direction.

5. The display device of claim 2, wherein:
the pixel group comprises a first pixel unit, a second pixel unit, a third pixel unit, and a fourth pixel unit, and
the pixel group is arranged repeatedly in the first direction and in the second direction.

6. The display device of claim 5, wherein:
the first pixel unit and the second pixel unit are arranged alternately in the first direction,
the first pixel unit and the third pixel unit are arranged alternately in the second direction, and
the third pixel unit and the fourth pixel unit are arranged alternately in the first direction.

7. The display device of claim 5, wherein, in the pixel group, the first pixel and the second pixel are arranged alternately in the first direction.

8. The display device of claim 5, wherein:
the first pixel unit and the third pixel unit include the rib area therein, and
the second pixel unit and the fourth pixel unit do not include the rib area therein.

9. The display device of claim 5, wherein:
in the first pixel unit, the rib area, the first pixel, and the second pixel are arranged sequentially in the first direction, and
in the third pixel unit, the first pixel, the rib area, and the second pixel are arranged sequentially in the first direction.

10. The display device of claim 5, wherein, in the display area, the first pixel, the rib area, and the first pixel are arranged sequentially in the second direction.

11. The display device of claim 5, wherein:
in the first pixel unit, the first pixel, the second pixel, and the rib area are arranged sequentially in the first direction, and
in the third pixel unit, the first pixel, the rib area, and the second pixel are arranged sequentially in the first direction.

12. The display device of claim 5, wherein, in the display area, the second pixel, the rib area, and the second pixel are arranged sequentially in the second direction.

13. The display device of claim 5, wherein:
the first pixel comprises a first sub-pixel, a second sub-pixel, and a third sub-pixel configured to emit different colors, and
the second pixel comprises a fourth sub-pixel, a fifth sub-pixel, and a sixth sub-pixel configured to emit different colors.

14. The display device of claim 13, wherein:
in the first pixel unit, the rib area, the first pixel, and the second pixel are arranged sequentially in the first direction, or the first pixel, the rib area, and the second pixel are arranged sequentially in the first direction, and
in the third pixel unit, the first pixel, the second pixel, and the rib area are arranged sequentially in the first direction, or the first pixel, the rib area, and the second pixel are arranged sequentially in the first direction.

15. The display device of claim 13, wherein, in the first pixel unit:
the rib area, the first sub-pixel, and the fourth sub-pixel are arranged sequentially in the first direction, and
the third sub-pixel, the rib area, and the sixth sub-pixel are arranged sequentially in the first direction.

16. The display device of claim 13, wherein, in the display area, the first sub-pixel, the rib area, the third sub-pixel, the rib area, and the second sub-pixel are arranged sequentially as a whole in the second direction.

17. The display device of claim 13, wherein, in the first pixel unit and the third pixel unit, a sequence in which the first sub-pixel, the second sub-pixel, and the rib area are arranged in the first direction is different for the first pixel unit and the third pixel unit.

18. The display device of claim 5, wherein, in each of the first pixel unit and the third pixel unit:
the rib area, the first pixel, and the second pixel are arranged sequentially in the first direction, or
the first pixel, the rib area, and the second pixel are arranged sequentially in the first direction.

19. An electronic device comprising:
an input module configured to receive, from an external source, commands or data for use in the electronic device;
at least one processor configured to process input data received from the input module, and to output image data and/or command data; and
a display device configured to implement one or more images by the at least one processor;
wherein the display device includes:
a display panel comprising a first pixel having a first viewing angle and a second pixel having a second viewing angle narrower than the first viewing angle, the first pixel and the second pixel in a display area; and
a light control layer configured to control a path of light, the light control layer comprising a light-blocking layer on the display panel,
wherein the display area comprises a rib area in an area other than a light-emitting area,
wherein the first pixel, the second pixel, and the rib area are arranged in a predetermined pattern to form a pixel group, and
wherein the rib area is arranged repeatedly and discontinuously in a first direction and in a second direction intersecting the first direction.

20. A display device comprising:
a display panel comprising a first pixel having a first viewing angle and a second pixel having a second viewing angle narrower than the first viewing angle, the first pixel and the second pixel in a display area; and
a light control layer configured to control a path of light, the light control layer comprising a light-blocking layer on the display panel,
wherein the display area comprises a rib area in an area other than a light-emitting area,
wherein the first pixel, the second pixel, and the rib area are arranged in a predetermined pattern to form a pixel group, and
wherein the rib area is arranged in a zigzag pattern.
